(19) United States
(12) Patent Application Publication
(10) Pub. No.: US 2026/0344393 A1
(43) Pub. Date: Oct. 29, 2026

(54) SEMICONDUCTOR DEVICE INCLUDING ETCH STOP LAYER

(71) Applicant: SAMSUNG ELECTRONICS CO., LTD., Suwon-si (KR)

(72) Inventors: Hwayeong Lee, Suwon-si (KR); Seung Min Lee, Suwon-si (KR); Juho Lee, Suwon-si (KR)

(73) Assignee: SAMSUNG ELECTRONICS CO., LTD., Suwon-si (KR)

(21) Appl. No.: 19/569,436

(22) Filed: Mar. 17, 2026

(30) Foreign Application Priority Data
Apr. 29, 2025 (KR) 10-2025-0056484

(51) Int. Cl. H10W 20/20; H10B 12/00; H10D 1/68; H10B 80/00; H10D 80/30; H10W 90/00

(52) U.S. Cl. CPC H10W 20/2134; H10B 12/482; H10B 12/488; H10B 12/50; H10D 1/714; H10B 12/03; H10B 12/05; H10B 80/00; H10D 80/30; H10W 90/792

(57) ABSTRACT

A semiconductor device may include: a polishing stop layer, an etch stop layer on an upper surface of the polishing stop layer, a semiconductor pattern on an upper surface of the etch stop layer, the semiconductor pattern extending in a first direction, a word line on at least a portion of an upper or lower surface of the semiconductor pattern, the word line extending in a second direction intersecting the first direction, a bit line extending in a third direction intersecting the first direction and the second direction, and connected to a first end of the semiconductor pattern, and a data storage element connected to a second end of the semiconductor pattern, opposite of the first end. An insulating material of the polishing stop layer may be different from an insulating material of the etch stop layer.

### CROSS-REFERENCE TO RELATED APPLICATION

This application claims priority to and the benefit of Korean Patent Application No. 10-2025-0056484, filed with the Korean Patent Office on Apr. 29, 2025, the disclosure of which is incorporated herein by reference in its entirety.

### BACKGROUND

### Field

Some embodiments of the present disclosure relate to a semiconductor device.

### Description of Related Art

Technologies are being developed to increase the integration density of semiconductor devices. For two-dimensional semiconductor memory devices, the integration density may be mainly determined by the area occupied by a unit memory cell, and this aspect of integration density may be affected by the level of fine pattern formation technology.

However, since the fine pattern formation technology may require expensive equipment, the integration of two-dimensional semiconductor devices is increasing, but is still limited. Accordingly, three-dimensional semiconductor memory devices having three-dimensionally arranged memory cells have been proposed.

### SUMMARY

According to some embodiments of the present disclosure, semiconductor devices with improved reliability may be provided.

According to some embodiments of the present disclosure, a semiconductor device having improved electrical performance may be provided.

According to some embodiments of the present disclosure, a semiconductor device may include: a polishing stop layer, an etch stop layer on an upper surface of the polishing stop layer, a semiconductor pattern on an upper surface of the etch stop layer, the semiconductor pattern extending in a first direction, a word line on at least a portion of an upper or lower surface of the semiconductor pattern, the word line extending in a second direction intersecting the first direction, a bit line extending in a third direction intersecting the first direction and the second direction, and connected to a first end of the semiconductor pattern, and a data storage element connected to a second end of the semiconductor pattern, opposite of the first end, wherein an insulating material of the polishing stop layer is different from an insulating material of the etch stop layer.

According to some embodiments of the present disclosure, a semiconductor device may include: a cell structure, and a peripheral circuit structure on an upper surface of the cell structure, wherein the cell structure includes: a polishing stop layer including an insulating material, an etch stop layer on an upper surface of the polishing stop layer, the etch stop layer including an insulating material different from the insulating material of the polishing stop layer; a semiconductor pattern on an upper surface of the etch stop layer and extending in a first direction, a word line on at least a portion of an upper or lower surface of the semiconductor pattern, the word line extending in a second direction intersecting the first direction, a bit line extending in a third direction intersecting the first direction and the second direction, and connected to a first end of the semiconductor pattern, a data storage element connected to a second end of the semiconductor pattern, opposite of the first end, and a cell wiring structure on the bit line and connected to the word line, and wherein the peripheral circuit structure includes: a peripheral substrate, a peripheral circuit wiring layer on the peripheral substrate and connected to the cell wiring structure, and a peripheral circuit between the peripheral circuit wiring layer and the peripheral substrate and connected to the peripheral circuit wiring layer.

According to some embodiments of the present disclosure, a semiconductor device may include: a first cell structure, a second cell structure on an upper surface of the first cell structure, and a peripheral circuit structure on an upper surface of the second cell structure, wherein each of the first cell structure and the second cell structure includes: an etch stop layer including an insulating material, a semiconductor pattern on an upper surface of the etch stop layer and extending in a first direction, a word line on at least a portion of an upper or lower surface of the semiconductor pattern, the word line extending in a second direction intersecting the first direction, a bit line extending in a third direction intersecting the first direction and the second direction, and connected to a first end of the semiconductor pattern, and a data storage element connected to a second end of the semiconductor pattern, opposite of the first end, wherein the first cell structure further includes a polishing stop layer below the etch stop layer of the first cell structure, the polishing stop layer including an insulating material that is different from the insulating material of the etch stop layer of the first cell structure, wherein the second cell structure further includes a cell wiring structure on the bit line of the second cell structure and connected to the word line of the first cell structure and the word line of the second cell structure, and wherein the peripheral circuit structure includes: a peripheral substrate, a peripheral circuit wiring layer on the peripheral substrate and connected to the cell wiring structure of the second cell structure, and a peripheral circuit between the peripheral circuit wiring layer and the peripheral substrate, and connected to the peripheral circuit wiring layer.

### BRIEF DESCRIPTION OF DRAWINGS

FIG. 1 is a plan view of a semiconductor device according to an embodiment.

FIG. 2 is a cross-sectional view taken along a line A–A′ of FIG. 1.

FIG. 3 is a cross-sectional view taken along a line B–B′ of FIG. 1.

FIGS. 4 to FIG. 8 are drawings for explaining a method for manufacturing a semiconductor device according to an embodiment.

FIGS. 9 and FIG. 10 cross-sectional views of semiconductor devices according to other embodiments.

FIGS. 11 to FIG. 21 are views for illustrating methods of manufacturing semiconductor devices according to the other embodiments.

### DETAILED DESCRIPTION

Hereinafter, various non-limiting example embodiments of the present disclosure will be described in detail with reference to the attached drawings so that a person having ordinary skill in the art to which the present disclosure pertains may easily implement embodiments of the present disclosure. Embodiments of the present disclosure may be embodied in many different forms and is not limited to the example embodiments described herein.

In order to clearly explain aspects of the present disclosure, parts irrelevant to the description may be omitted, and the same reference numerals are used for identical or similar components throughout the specification.

In addition, the size and thickness of each component shown in the drawing may be arbitrarily shown for convenience of explanation, and so the present disclosure is not limited to what is shown. To clearly represent the various layers and areas in the drawing, thicknesses may be enlarged. And in the drawing, for convenience of explanation, the thickness of some layers and areas may be exaggerated.

Also, when a part, such as a layer, membrane, region, or plate, is described as “over” or “on” another part, this includes not only cases where it is “directly over” the other part, but also cases where there are other parts in between. Conversely, when a part is described as being “directly above” another part, there is no other part in between. Also, being “above” a reference part means being located above or below the reference part, and does not necessarily mean being located “above” in the direction opposite of gravity.

Additionally, throughout the specification, whenever a part is described to “include” a component, this does not mean that it excludes other components, but rather that it may include other components, unless otherwise specifically stated.

Additionally, throughout the specification, “in a plan view,” means when the target portion is viewed from above, and “in a cross-section” means the target portion is viewed from the side in a cross-section cut vertically.

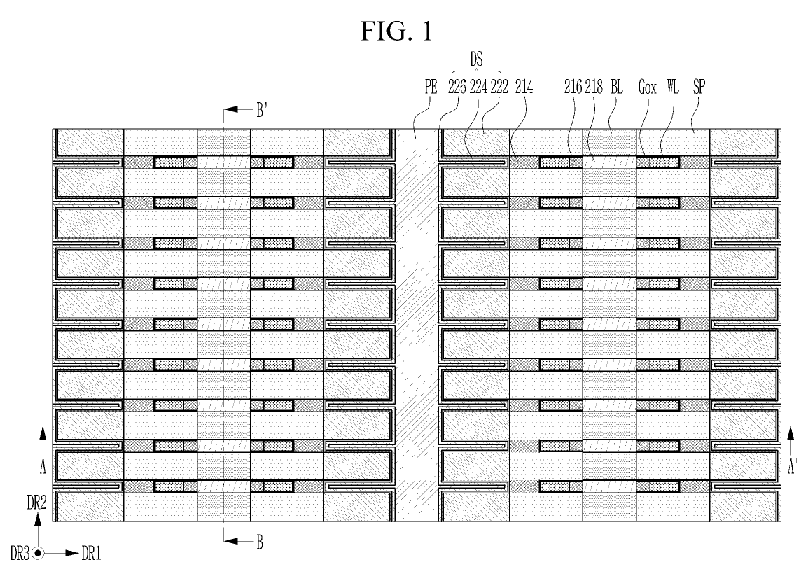

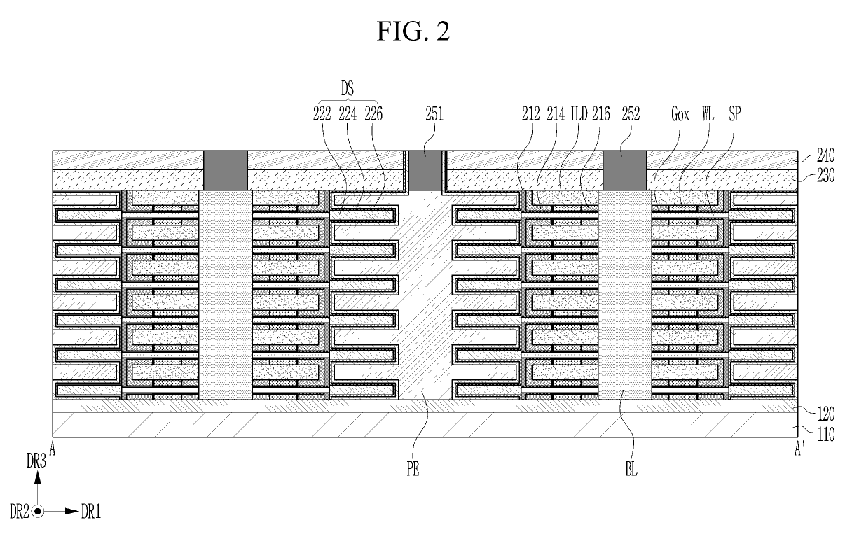

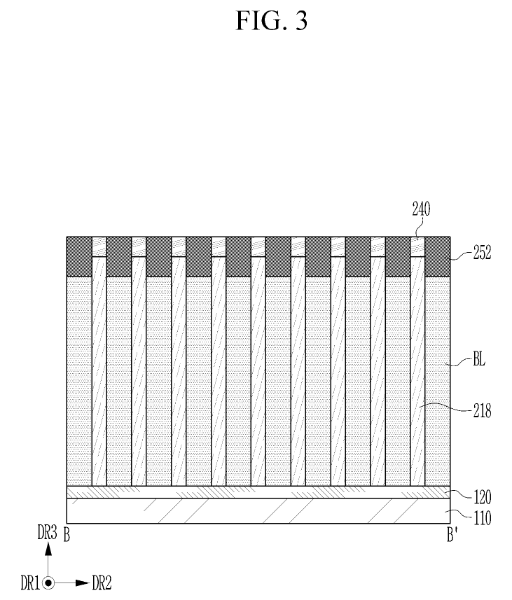

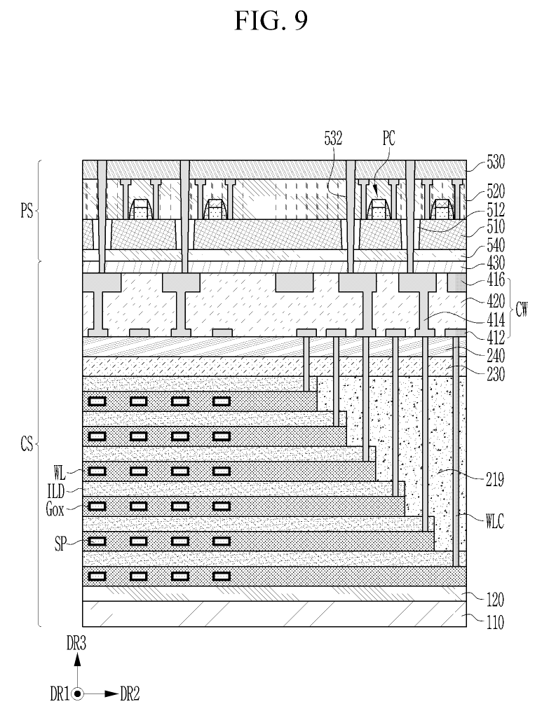

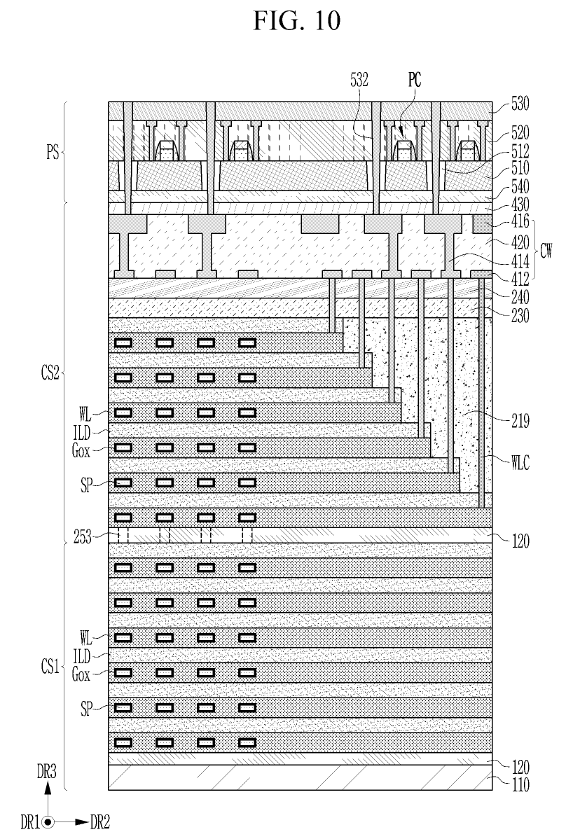

FIG. 1 is a plan view of a semiconductor device according to an embodiment. FIG. 2 is a cross-sectional view taken along a line A-A’ of FIG. 1. FIG. 3 is a cross-sectional view taken along a line B-B’ of FIG. 1. A semiconductor device according to an embodiment described with reference to FIGS. 1 to FIG. 3 may be included in a cell structure CS, a first cell structure CS1, and a second cell structure CS2 of FIGS. 9 and FIG. 10.

Referring to FIGS. 1 to 3, the semiconductor device according to an embodiment may include a polishing stop layer 110, an etch stop layer 120, bit lines BL, semiconductor patterns SP, word lines WL, and data storage elements DS.

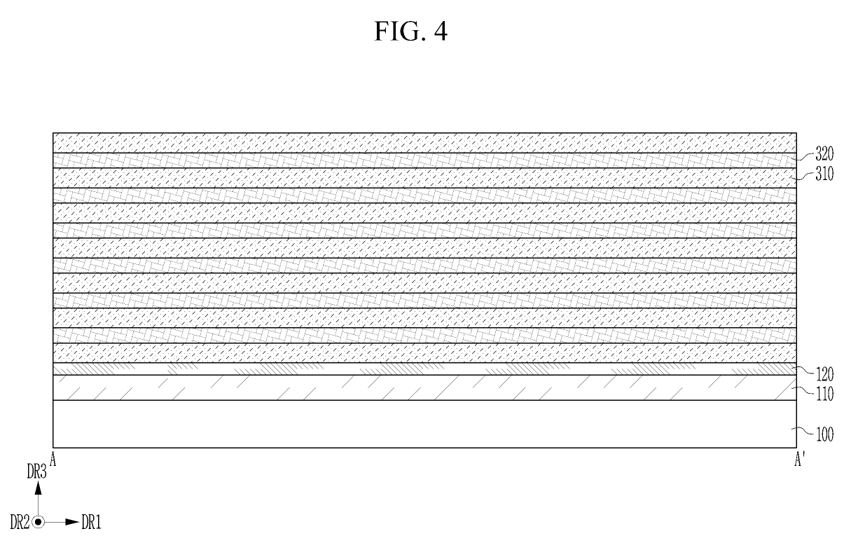

The semiconductor device according to an embodiment may not include a substrate 100 of FIGS. 4 to FIG. 7. During the process of manufacturing the semiconductor device according to an embodiment, the substrate 100 may be removed. For example, the substrate 100 may be removed through a grinding process. The polishing stop layer 110 may serve as a stop layer in a polishing process for removing the substrate 100.

The polishing stop layer 110 may have a shape extending in a first direction DR1 and a second direction DR2. The polishing stop layer 110 may have an upper surface parallel to the first direction DR1 and the second direction DR2. Here, the second direction DR2 may be a direction intersecting the first direction DR1. For example, the first direction DR1 and the second direction DR2 may be orthogonal to each other. The upper surface of the polishing stop layer 110 may have a flat shape.

The polishing stop layer 110 may include an insulating material. For example, the polishing stop layer 110 may include, but is not limited to, at least one from among silicon oxide (SiO₂), silicon nitride (SiN), silicon oxycarbonate (SiOC), silicon oxynitride (SiON), and silicon oxycarbonitride (SiOCN).

The etch stop layer 120 may be positioned on the polishing stop layer 110. The etch stop layer 120 may have a shape extending in the first direction DR1 and the second direction DR2. The etch stop layer 120 may have an upper surface parallel to the first direction DR1 and the second direction DR2. The upper surface of the etch stop layer 120 may have a flat shape.

The etch stop layer 120 may include an insulating material. For example, the etch stop layer 120 may include at least one from among silicon oxide (SiO₂), silicon nitride (SiN), silicon oxycarbonate (SiOC), silicon oxynitride (SiON), silicon oxycarbonitride (SiOCN), hafnium oxide (HfO₂), zirconium oxide (ZrO₂), and beryllium oxide (BeO).

The polishing stop layer 110 and the etch stop layer 120 may include different insulating materials from each other. The polishing stop layer 110 and the etch stop layer 120 may include materials having different etch rates under the same conditions. For example, the polishing stop layer 110 may include at least one from among silicon oxide (SiO₂), silicon nitride (SiN), silicon oxycarbonate (SiOC), silicon oxynitride (SiON), silicon oxycarbonitride (SiOCN), hafnium oxide (HfO₂), zirconium oxide (ZrO₂), and beryllium oxide (BeO).

The bit line BL may be positioned on the etch stop layer 120. The bit line BL may have a form extending in a third direction DR3. The third direction DR3 may be a direction intersecting the first direction DR1 and the second direction DR2. For example, the third direction DR3 and the first direction DR1 may be orthogonal to each other, and the third direction DR3 and the second direction DR2 may be orthogonal to each other. For example, the third direction DR3 may be a direction perpendicular to the upper surface of the etch stop layer 120.

The bit line BL may be in contact with the etch stop layer 120. The lower surface of the bit line BL may be in contact with the upper surface of the etch stop layer 120. The lower surface of the bit line BL may be positioned at a same level as a level of the upper surface of the etch stop layer 120 in the third direction DR3.

The bit line BL may be connected to the plurality of semiconductor patterns SP on opposite sides of the bit line BL in the first direction DR1. The plurality of semiconductor patterns SP may be positioned to be spaced apart from each other in the third direction DR3 on the opposite sides of the bit line BL in the first direction DR1. The bit line BL may be connected to one end of the semiconductor pattern SP. Here, one side of the semiconductor pattern SP may mean a side where the semiconductor pattern SP is connected to the bit line BL, and the opposite side of the semiconductor pattern SP may mean a side where the semiconductor pattern SP is connected to the data storage element DS. The semiconductor pattern SP may be positioned between the data storage element DS and the bit line BL. The semiconductor pattern SP may be positioned between the data storage element DS and the bit line BL in the first direction DR1. For example, one side of the semiconductor pattern SP may be called the first side, and the opposite side of the semiconductor pattern SP may be called the second side.

The bit line BL may be positioned to overlap with the semiconductor patterns SP in the first direction DR1. The bit line BL may be positioned so as not to overlap with the semiconductor patterns SP in the second direction DR2, but is not limited thereto. For example, the bit line BL may overlap with one end of at least one of the semiconductor patterns SP in the second direction DR2.

One side of the bit line BL may be in contact with an interlayer dielectric layer ILD and a second spacer 216 positioned between the plurality of semiconductor patterns SP in the third direction DR3, but is not limited thereto. For example, in some embodiments, additional insulating patterns may be further arranged, or the interlayer dielectric layer ILD and the second spacer 216 may be formed from a single insulating pattern.

The plurality of bit lines BL may be positioned on the etch stop layer 120. The plurality of bit lines BL may be positioned so as to be spaced apart in the first direction DR1. Additionally, the plurality of bit lines BL may be positioned to be spaced apart in the second direction DR2. The plurality of semiconductor patterns SP, the plurality of word lines WL, and the plurality of data storage elements DS may be positioned between the plurality of bit lines BL in the first direction DR1. A separation insulating pattern 218 may be positioned between the plurality of bit lines BL in the second direction DR2.

The bit line BL may include a conductive material. For example, the bit line BL may include any one from among a doped semiconductor material such as doped silicon (Si) or doped germanium (Ge), a conductive metal nitride such as titanium nitride (TiN) or tantalum nitride (TaN), a metal such as tungsten (W), titanium (Ti), or tantalum (Ta), or a metal-semiconductor compound such as tungsten silicide (WSiₓ), cobalt silicide (CoSiₓ), or titanium silicide (TiSiₓ).

The semiconductor patterns SP may be positioned on the etch stop layer 120. The semiconductor patterns SP may have a shape extending in the first direction DR1. For example, the semiconductor patterns SP may have a bar shape extending in the first direction DR1. The semiconductor patterns SP may be positioned between the bit line BL and the data storage element DS.

Here, one side of the semiconductor pattern SP may mean a side where the semiconductor pattern SP is connected to the bit line BL, and the opposite side of the semiconductor pattern SP may mean a side where the semiconductor pattern SP is connected to the data storage element DS. The semiconductor patterns SP may be positioned between the data storage element DS and the bit line BL. For example, one side of the semiconductor patterns SP may be called a first side, and the opposite side of the semiconductor patterns SP may be called a second side.

The semiconductor patterns SP may be connected to the bit line BL. One end of the semiconductor patterns SP may be connected to the bit line BL. One side of the semiconductor patterns SP may be in contact with the side of the bit line BL. However, in some embodiments, one end of the semiconductor patterns SP may be surrounded by the bit line BL. In other words, in some embodiments, the semiconductor patterns SP may be connected to the bit line BL in a form that partially protrudes into the bit line BL.

The opposite end of the semiconductor pattern SP may be connected to the data storage element DS. The opposite side of the semiconductor pattern SP may be in contact with a first electrode 222 of the data storage element DS. The thickness of the semiconductor pattern SP in the third direction DR3 may be smaller than the thickness of the first electrode 222 in the third direction DR3, but is not limited thereto.

A portion of a semiconductor pattern SP may be surrounded by the word line WL. A portion of the upper surface of the semiconductor pattern SP may be covered by the word line WL. A portion of the lower surface of the semiconductor pattern SP may be covered by the word line WL. A portion of the side surface of the semiconductor pattern SP in the second direction DR2 may be covered by the word line WL. The semiconductor pattern SP may be positioned so as to penetrate the word line WL in the first direction DR1. A gate insulating pattern Gox may be positioned between the semiconductor pattern SP and the word line WL.

The plurality of semiconductor patterns SP may be positioned on the etch stop layer 120. The plurality of semiconductor patterns SP may be positioned to be spaced apart in the first direction DR1, the second direction DR2, and the third direction DR3. The plurality of semiconductor patterns SP may be stacked so as to be spaced apart from each other in the third direction DR3. For example, the plurality of semiconductor patterns SP connected to one bit line BL may be arranged to be spaced apart from each other in the third direction DR3. Additionally, the plurality of semiconductor patterns SP may be arranged to be spaced apart from each other in the first direction DR1 and the second direction DR2 along bit lines BL that are arranged to be spaced apart from each other in the first direction DR1 and the second direction DR2. The bit line BL or the data storage element DS may be positioned between the plurality of semiconductor patterns SP in the first direction DR1. The word line WL extending in the second direction DR2 may be positioned between the plurality of semiconductor patterns SP in the second direction DR2. The interlayer dielectric layer ILD, an intermediate insulating layer 212, a first spacer 214, and the second spacer 216 may be positioned between the plurality of semiconductor patterns SP in the third direction DR3.

The semiconductor pattern SP may include a semiconductor material. The semiconductor pattern SP may include an oxide semiconductor material. The oxide semiconductor material may include at least one selected from among IGZO (InGaZnO), ZrOₓ, ZTO (ZnSnO), ITZO (InSnZnO), Sn-IGZO, IWO (InWO), IZO (InZnO), ZnO, ZnON, YZO (yttrium-doped zinc oxide), InGaSiO, InO, SnO, TiO, ZnON, MgZnO, InZnO, ZrInZnO, HfInZnO, SnInZnO, AlSnInZnO, SiInZnO, AlZnSnO, GaZnSnO, and ZrZnSnO, but is not limited thereto. The semiconductor pattern SP may further include at least one dopant selected from among aluminum (Al), boron (B), arsenic (As), fluorine (F), and hydrogen (H), in addition to at least one oxide semiconductor material selected from among the above-mentioned oxide semiconductor materials. Alternatively, the semiconductor pattern SP may include poly silicon. However, without limitation thereto, the semiconductor pattern SP may include, for example, silicon (Si), germanium (Ge), or silicon-germanium (SiGe).

The semiconductor pattern SP may include a channel region, a first impurity region, and a second impurity region. The first impurity region and the second impurity region may be regions in which the semiconductor pattern SP is doped with impurities. The first impurity region and the second impurity region may have a conductivity type of n-type or p-type. For example, the first impurity region and the second impurity region may be positioned at each end of the semiconductor pattern SP in the first direction DR1. For example, the first impurity region of the semiconductor pattern SP may be connected to the bit line BL, and the second impurity region of the semiconductor pattern SP may be connected to the data storage element DS. The channel region may be positioned between the first impurity region and the second impurity region. The channel region of the semiconductor pattern SP may be surrounded by a word line WL.

The word line WL may be positioned on the semiconductor pattern SP. The word line WL may have a shape extending in the second direction DR2. For example, the word line WL may have a bar shape extending in the second direction.

For example, the word line WL may be positioned to surround a portion of the semiconductor pattern SP. The word line WL may extend in the second direction DR2 and surround the plurality of semiconductor patterns SP positioned so as to be spaced apart in the second direction DR2. The word line WL may surround at least a portion of an upper or lower surface of the semiconductor pattern SP. The word line WL may cover a portion of the upper surface of the semiconductor pattern SP. The word line WL may cover a portion of lower surface of the semiconductor pattern SP. The word line WL may cover a portion of the side surface of the semiconductor pattern SP in the second direction DR2. The word line WL may cover a center area of the semiconductor pattern SP in the first direction DR1. The word line WL may cover the channel region positioned between the first impurity region and the second impurity region of the semiconductor pattern SP. The word line WL may have a form extending in the second direction DR2, and the semiconductor pattern SP may be arranged in a form penetrating the word line WL in the first direction DR1. In some embodiments, a pair of word lines WL may be respectively arranged on the upper surface and lower surface of the semiconductor pattern SP.

The gate insulating pattern Gox may be positioned between the word line WL and the semiconductor pattern SP. The word line WL and the semiconductor pattern SP may be positioned to be separated by the gate insulating pattern Gox. The word line WL and the semiconductor pattern SP may not contact each other.

The plurality of word lines WL may be positioned on the etch stop layer 120. The plurality of word lines WL may be positioned so as to be spaced apart in the first direction DR1 and the third direction DR3 from each other. The bit line BL or the data storage element DS may be positioned between the plurality of word lines WL in the first direction DR1. The interlayer dielectric layer ILD may be positioned between the plurality of word lines WL in the third direction DR3.

The word line WL may include a conductive material. For example, the word line WL may include any one from among a doped semiconductor material such as doped silicon (Si) or doped germanium (Ge), a conductive metal nitride such as titanium nitride (TiN) or tantalum nitride (TaN), a metal such as tungsten (W), titanium (Ti), or tantalum (Ta), or a metal-semiconductor compound such as tungsten silicide (WSiₓ), cobalt silicide (CoSiₓ), or titanium silicide (TiSiₓ).

The data storage element DS may be connected to the semiconductor pattern SP. One end of the semiconductor pattern SP may be connected to the bit line BL, and the opposite end of the semiconductor pattern SP may be connected to the data storage element DS. The data storage element DS may extend in the first direction DR1.

The plurality of data storage elements DS may be positioned on the etch stop layer 120. The plurality of data storage elements DS may be respectively connected to the plurality of semiconductor patterns SP. The plurality of data storage elements DS may be positioned so as to be spaced apart from each other in the first direction DR1, the second direction DR2, and the third direction DR3. The semiconductor pattern SP and the bit line BL, or a plate electrode PE, may be positioned between the plurality of data storage elements DS in the first direction DR1. The plate electrode PE may be positioned between the plurality of data storage elements DS in the third direction DR3. The plate electrode PE may be positioned between the plurality of data storage elements DS in the second direction DR2. However, embodiments are not limited thereto, and for example, the plurality of data storage elements DS may be positioned consecutively without being spaced apart from each other in the second direction DR2.

The data storage element DS may include the first electrode 222, a dielectric film 224, and a second electrode 226.

The first electrode 222 may be connected to the opposite end of the semiconductor pattern SP. One end of the first electrode 222 may be connected to the semiconductor pattern SP. Here, one side of the first electrode 222 may mean a side connected to the semiconductor pattern SP, and the opposite side of the first electrode 222 may mean a side positioned opposite the side connected to the semiconductor pattern SP. The first electrode 222 may cover the opposite side of the semiconductor pattern SP. The first electrode 222 may be in contact with the opposite side of the semiconductor pattern SP. The first electrode 222 may be positioned at substantially the same level as the semiconductor pattern SP in the third direction DR3. The first electrode 222 may be aligned parallel to the semiconductor pattern SP in the first direction DR1. According to some embodiments, the first electrode 222 may have a shape that surrounds the opposite end of the semiconductor pattern SP.

The first electrode 222 may have a shape extending in the first direction DR1. The first electrode 222 may have a bar or pillar shape extending in the first direction DR1, but is not limited thereto. For example, the first electrode 222 may have a cylinder shape with a hollow center. The width of the first electrode 222 in the second direction DR2 and the thickness of the first electrode 222 in the third direction DR3 may be greater than the width of the semiconductor pattern SP in the second direction DR2 and the thickness of the semiconductor pattern SP in the third direction DR3, but is not limited thereto. For example, the width in the second direction DR2 and the thickness in the third direction DR3 of the first electrode 222 may be substantially the same as the width in the second direction DR2 and the thickness in the third direction DR3 of the semiconductor pattern SP.

The plurality of first electrodes 222 may be positioned on the etch stop layer 120. The plurality of first electrodes 222 may be respectively connected to the opposite end of the plurality of semiconductor patterns SP.

The first electrode 222 may include a conductive material. The first electrode 222 may include, for example, at least one from among a metal material such as titanium (Ti), tantalum (Ta), tungsten (W), copper (Cu), aluminum (Al), platinum (Pt), iridium (Ir), or ruthenium (Ru); a conductive metal nitride such as titanium nitride (TiN), molybdenum nitride (MoN), vanadium nitride (VN), niobium nitride (NbN), or tantalum nitride (TaN); a conductive metal oxide such as ruthenium oxide (RuOₓ), iridium oxide (IrO), indium tin oxide (ITO), molybdenum oxide (MoOₓ), and vanadium oxide (VOₓ); or a doped semiconductor material such as doped silicon (doped Si) or doped germanium (doped Ge).

The dielectric film 224 may be positioned on the first electrode 222. The dielectric film 224 may be positioned between the first electrode 222 and the second electrode 226. The dielectric film 224 may be conformally positioned on the first electrode 222.

The dielectric film 224 may cover a portion of the upper, lower, and side surfaces of the first electrode 222. Additionally, the dielectric film 224 may cover the opposite side of the first electrode 222. Here, the opposite side of the first electrode 222 may mean a side opposite to one side of the first electrode 222 where the first electrode 222 and the semiconductor pattern SP are connected.

The plurality of data storage elements DS positioned so as to be spaced apart in the third direction DR3 may share one dielectric film 224.

The dielectric film 224 may be positioned on the intermediate insulating layer 212. The dielectric film 224 may be positioned on the side of the intermediate insulating layer 212 in the first direction DR1. The dielectric film 224 may be conformally positioned on the intermediate insulating layer 212 and the first electrode 222. Here, the intermediate insulating layer 212 may be positioned to cover the opposite end of the semiconductor pattern SP.

In an embodiment, the dielectric film 224 may extend in the third direction DR3 to cover a side surface of a first connection pad 251 positioned on the plate electrode PE.

The dielectric film 224 may include an insulating material. The dielectric film 224 may include a silicon oxide film, a silicon nitride film, a high-k dielectric film having a higher dielectric constant than a dielectric constant of the silicon oxide film, or a combination thereof. Here, the high-k dielectric film may be made of a metal oxide or a metal oxide nitride. For example, high-k dielectric films usable as the dielectric film 224 may include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), or combinations thereof.

The second electrode 226 may be positioned on the dielectric film 224. The second electrode 226 may be conformally positioned on the dielectric film 224. The second electrode 226 may be positioned in a space between the plurality of first electrodes 222 spaced apart in the third direction DR3. The plurality of data storage elements DS positioned so as to be spaced apart in the third direction DR3 may share one second electrode 226.

In an embodiment, the second electrode 226 may extend in the third direction DR3 to cover a side surface of the first connection pad 251 positioned on the plate electrode PE.

The second electrode 226 may include a conductive material. The second electrode 226 may include, for example, at least one from among a metal material such as titanium (Ti), tantalum (Ta), tungsten (W), copper (Cu), aluminum (Al), platinum (Pt), iridium (Ir), or ruthenium (Ru), a conductive metal nitride such as titanium nitride (TiN), molybdenum nitride (MoN), vanadium nitride (VN), niobium nitride (NbN), or tantalum nitride (TaN), a conductive metal oxide such as ruthenium oxide (RuOₓ), iridium oxide (IrO), indium tin oxide (ITO), molybdenum oxide (MoOₓ), and vanadium oxide (VOₓ), or a doped semiconductor material such as doped silicon (doped Si) or doped germanium (doped Ge).

The semiconductor device according to an embodiment may further include the interlayer dielectric layer ILD, the gate insulating pattern Gox, the intermediate insulating layer 212, the first spacer 214, the second spacer 216, the separation insulating pattern 218, the plate electrode PE, a shield layer 230, an upper insulating layer 240, the first connection pad 251, and a second connection pad 252.

The interlayer dielectric layer ILD may be positioned between the plurality of semiconductor patterns SP in the third direction DR3. The interlayer dielectric layer ILD may be positioned on the word line WL. The interlayer dielectric layer ILD may be positioned between the plurality of word lines WL in the third direction DR3. The interlayer dielectric layer ILD may be positioned to contact the interlayer dielectric layer ILD. The interlayer dielectric layer ILD may be positioned on the first spacer 214. One end of the interlayer dielectric layer ILD may be surrounded by the first spacer 214. The interlayer dielectric layer ILD may be positioned on the second spacer 216. The opposite end of the interlayer dielectric layer ILD may be surrounded by the second spacer 216. The interlayer dielectric layer ILD may be positioned between the first spacer 214 and the bit line BL. For example, one side of the interlayer dielectric layer ILD may be in contact with the bit line BL, and the opposite side of the interlayer dielectric layer ILD may be in contact with the first spacer 214.

The interlayer dielectric layer ILD may include an insulating material. By way of example, the interlayer dielectric layer ILD may include, but is not limited to, at least one from among silicon oxide (SiO₂), silicon nitride (SiN), and silicon oxynitride (SiON).

The gate insulating pattern Gox may be placed between the word line WL and the semiconductor pattern SP. The semiconductor pattern SP and the word line WL may be arranged to be spaced apart in the third direction DR3 with the gate insulating pattern Gox interposed therebetween. The gate insulating pattern Gox may be in contact with the semiconductor pattern SP. The gate insulating pattern Gox may be further positioned between the first spacer 214 and the semiconductor pattern SP. The gate insulating pattern Gox may cover a portion of the upper surface of the semiconductor pattern SP. The gate insulating pattern Gox may cover a portion of lower surface of the semiconductor pattern SP. The gate insulating pattern Gox may cover a portion of the side surface of the semiconductor pattern SP in the second direction DR2. The gate insulating pattern Gox may cover a center area of the semiconductor pattern SP in the first direction DR1. The gate insulating pattern Gox may cover the channel region positioned between the first impurity region and the second impurity region of the semiconductor pattern SP.

Additionally, in some embodiments, the gate insulating pattern Gox may be further positioned between the word line WL and the second spacer 216. For example, the gate insulating pattern Gox may have an “L” shape in the cross-section in the first direction DR1 and the third direction DR3, but is not limited thereto. For example, the gate insulating pattern Gox may have a bar shape extending along the semiconductor pattern SP in the cross-section in the first direction DR1 and the third direction DR3.

The gate insulating pattern Gox may include an insulating material. The gate insulating pattern Gox may include a silicon oxide film, a silicon oxynitride film, a high-k film having a higher dielectric constant than a dielectric constant of the silicon oxide film, or a combination thereof. Here, the high-k dielectric film may be made of a metal oxide or a metal oxide nitride. For example, high-k dielectric films usable as gate insulating pattern Gox may include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃) or combinations thereof.

The intermediate insulating layer 212 may cover the opposite end of the semiconductor pattern SP. The semiconductor pattern SP may be positioned so as to penetrate the intermediate insulating layer 212 in the first direction DR1. The intermediate insulating layer 212 may be positioned between the first spacer 214 and the data storage element DS. The intermediate insulating layer 212 may be positioned between the first spacer 214 and the dielectric film 224. Additionally, the intermediate insulating layer 212 may be further positioned between the first spacer 214 and the semiconductor pattern SP. Additionally, by way of example, the intermediate insulating layer 212 may have a “U” shape in the cross-section in the first direction DR1 and the third direction DR3, but is not limited thereto.

The first spacer 214 may be positioned between the word line WL and the data storage element DS. The first spacer 214 may be positioned between the intermediate insulating layer 212 and the word line WL. The first spacer 214 may be positioned between the intermediate insulating layer 212 and the interlayer dielectric layer ILD. The first spacer 214 may have a form that surrounds a portion of the semiconductor pattern SP between the word line WL and the data storage element DS.

The second spacer 216 may be positioned between the word line WL and the bit line BL. The second spacer 216 may have a form that surrounds a portion of the semiconductor pattern SP between the word line WL and the bit line BL. The second spacer 216 may surround one end of the semiconductor pattern SP. The gate insulating pattern Gox may be positioned between the second spacer 216 and the semiconductor pattern SP.

The first spacer 214 and the second spacer 216 may be respectively positioned on opposite sides of the word line WL in the first direction DR1.

The intermediate insulating layer 212, the first spacer 214, and the second spacer 216 may include an insulating material. The intermediate insulating layer 212, the first spacer 214, and the second spacer 216 may include the same insulating material as each other. Alternatively, at least one of the intermediate insulating layer 212, the first spacer 214, and the second spacer 216 may include different insulating materials. For example, the intermediate insulating layer 212, the first spacer 214, and the second spacer 216 may include, but are not limited to, at least one from among silicon oxide (SiO₂), silicon nitride (SiN), silicon oxycarbonate (SiOC), and silicon oxynitride (SiON). The intermediate insulating layer 212, the first spacer 214, and the second spacer 216 may each be formed individually.

The separation insulating pattern 218 may be positioned on the etch stop layer 120. The separation insulating pattern 218 may be in contact with the etch stop layer 120. The lower surface of the separation insulating pattern 218 may be positioned at a same level as a level of the upper surface of the etch stop layer 120 in the third direction DR3. The separation insulating pattern 218 may be positioned between the plurality of bit lines BL spaced apart in the second direction DR2. The plurality of bit lines BL may be electrically isolated from each other by the separation insulating pattern 218.

The upper surface of the separation insulating pattern 218 may be positioned above the upper surface of the bit line BL in the third direction DR3, but is not limited thereto. For example, the upper surface of the separation insulating pattern 218 may be positioned at a same level as a level of the upper surface of the bit line BL in the third direction DR3. The upper surface of the separation insulating pattern 218 may be positioned at a same level as a level of the upper surface of the shield layer 230 in the third direction DR3, but is not limited thereto. For example, the upper surface of the separation insulating pattern 218 may be positioned above the upper surface of the shield layer 230. The separation insulating pattern 218 may have a form extending in the third direction DR3.

The plate electrode PE may be positioned on the etch stop layer 120. The plate electrode PE may be in contact with the etch stop layer 120. The lower surface of the plate electrode PE may be positioned at a same level as a level of the upper surface of the etch stop layer 120 in the third direction DR3.

The plate electrode PE may cover the data storage element DS. One plate electrode PE may cover the plurality of data storage elements DS. The plate electrode PE may cover the second electrode 226. The plate electrode PE may be in contact with the plurality of second electrodes 226. The plate electrode PE may be positioned between the plurality of data storage elements DS spaced apart in the third direction DR3. The plate electrode PE may fill the space between the plurality of data storage elements DS positioned spaced apart in the third direction DR3. The plate electrode PE may be positioned spaced apart in the first direction DR1 and may be positioned between the plurality of data storage elements DS facing each other. The plate electrodes PE may be positioned spaced apart in the first direction DR1 and may fill the space between the plurality of data storage elements DS facing each other. In some embodiments, the plate electrode PE may be considered as being included as a component of the data storage element DS.

The shield layer 230 may be positioned above the plurality of semiconductor patterns SP stacked in the third direction DR3. The shield layer 230 may be positioned above the uppermost one of semiconductor patterns SP. The shield layer 230 may be positioned above the plurality of word lines WL stacked in the third direction DR3. The shield layer 230 may be positioned above the uppermost one of word lines WL. The shield layer 230 may be positioned on the data storage elements DS stacked in the third direction DR3. The shield layer 230 may be positioned above the bit line BL. The lower surface of the shield layer 230 may be positioned at a same level as a level of the upper surface of the bit line BL in the third direction DR3. The shield layer 230 may be positioned on the interlayer dielectric layers ILD that are spaced apart in the third direction DR3. The shield layer 230 may be positioned above the uppermost one of the interlayer dielectric layers ILD that are spaced apart in the third direction DR3.

The shield layer 230 may have a shape extending in the first direction DR1. The shield layer 230 may cover the side surfaces of the first connection pad 251 and the second connection pad 252. An additional insulating layer may be positioned between the shield layer 230 and the first connection pad 251, and between the shield layer 230 and the second connection pad 252. In FIG. 2, the lower surface of the shield layer 230 and the upper surface of the uppermost interlayer dielectric layer ILD are illustrated as being in contact, but this is not limited thereto. For example, other components may be additionally placed between the lower surface of the shield layer 230 and the interlayer dielectric layer ILD.

The shield layer 230 may include a semiconductor material. The shield layer 230 may include, but is not limited to, poly silicon. For example, the shield layer 230 may include an oxide semiconductor material. The oxide semiconductor material may include at least one selected from among IGZO (InGaZnO), ZrOₓ, ZTO (ZnSnO), ITZO (InSnZnO), Sn-IGZO, IWO (InWO), IZO (InZnO), ZnO, ZnON, YZO (yttrium-doped zinc oxide), InGaSiO, InO, SnO, TiO, ZnON, MgZnO, InZnO, ZrInZnO, HfInZnO, SnInZnO, AlSnInZnO, SiInZnO, AlZnSnO, GaZnSnO, and ZrZnSnO, but is not limited thereto. The shield layer 230 may further include at least one dopant selected from among aluminum (Al), boron (B), arsenic (As), fluorine (F), and hydrogen (H) in addition to at least one oxide semiconductor material selected from the oxide semiconductor materials describes above. Alternatively, the shield layer 230 may include an insulating material such as silicon oxide (SiO₂) and silicon nitride (SiN).

The upper insulating layer 240 may be positioned on the shield layer 230. Additionally, the upper insulating layer 240 may be positioned on the separation insulating pattern 218. The upper insulating layer 240 may cover the side surfaces of the first connection pad 251 and the second connection pad 252. The upper insulating layer 240 may include an insulating material. For example, the upper insulating layer 240 may include an insulating material such as, but not limited to, silicon oxide (SiO₂) and silicon nitride (SiN).

In FIG. 2, the upper insulating layer 240 is illustrated as a single layer, but is not limited thereto. For example, the upper insulating layer 240 may include two or more insulating layers.

The second connection pad 252 may be positioned on the bit line BL. The first connection pad 251 may be positioned on the plate electrode PE. The first connection pad 251 and the second connection pad 252 may be positioned to penetrate the shield layer 230 and the upper insulating layer 240. The side surfaces of each of the plurality of first connection pads 251 may be covered by the dielectric film 224 and the second electrode 226. The dielectric film 224 and the second electrode 226 extending in the third direction DR3 may be further positioned between the first connection pad 251 and the shield layer 230. Additionally, the dielectric film 224 and the second electrode 226 may be further positioned between the first connection pad 251 and the upper insulating layer 240. The second connection pads 252 may be positioned so as to be spaced apart in the second direction DR2 along the plurality of bit lines BL that are positioned so as to be spaced apart in the second direction DR2.

The width of the second connection pad 252 in the second direction DR2 may be substantially equal to or similar to the width of the bit line BL in the second direction DR2. The upper surfaces of the first connection pad 251 and the second connection pad 252 may be positioned at a same level as a level of the upper surface of the upper insulating layer 240 in the third direction DR3. According to some embodiments, an additional insulating layer may be positioned between the second connecting pad 252 and the shield layer 230.

The first connection pad 251 and the second connection pad 252 may include a conductive material. The first connection pad 251 and the second connection pad 252 may include at least one from among a metal material such as titanium (Ti), tantalum (Ta), tungsten (W), copper (Cu), aluminum (Al), platinum (Pt), iridium (Ir), or ruthenium (Ru); a conductive metal nitride such as titanium nitride (TiN), molybdenum nitride (MoN), vanadium nitride (VN), niobium nitride (NbN), or tantalum nitride (TaN); a conductive metal oxide such as ruthenium oxide (RuOₓ), iridium oxide (IrO), indium tin oxide (ITO), molybdenum oxide (MoOₓ), and vanadium oxide (VOₓ); or a doped semiconductor material such as doped silicon (doped Si) or doped germanium (doped Ge).

FIGS. 4 to 8 are drawings for explaining a method for manufacturing a semiconductor device according to an embodiment.

Referring to FIG. 4, the polishing stop layer 110 may be formed on the substrate 100. The etch stop layer 120 may be formed on the polishing stop layer 110. For example, the polishing stop layer 110 and the etch stop layer 120 may be formed by a deposition method, but are not limited thereto. The substrate 100 may be called a cell substrate, but may be removed in a later process.

Semiconductor material layers 310 and insulating material layers 320 may be alternately and repeatedly stacked in the third direction DR3 on the etch stop layer 120. The thickness of the semiconductor material layer 310 in the third direction DR3 may be thicker than the thickness of the insulating material layer 320 in the third direction DR3, but is not limited thereto.

For example, the semiconductor material layer 310 and the insulating material layer 320 may be formed on the etch stop layer 120 by a deposition method. For example, the semiconductor material layer 310 and the insulating material layer 320 may be formed by any one from among atomic layer deposition (ALD), chemical vapor deposition (CVD), and physical vapor deposition (PVD) methods, but are not limited thereto.

The semiconductor material layer 310 may include a semiconductor material. For example, the semiconductor material layer 310 may include polysilicon. However, embodiments are not limited thereto, and the semiconductor material layer 310 may include materials such as silicon (Si), germanium (Ge), silicon-germanium (SiGe), and oxide semiconductors. Here, the oxide semiconductor material may be formed of at least one selected from among IGZO (InGaZnO), ZrOₓ, ZTO (ZnSnO), ITZO (InSnZnO), Sn-IGZO, IWO (InWO), IZO (InZnO), ZnO, ZnON, YZO (yttrium-doped zinc oxide), InGaSiO, InO, SnO, TiO, ZnON, MgZnO, InZnO, ZrInZnO, HfInZnO, SnInZnO, AlSnInZnO, SiInZnO, AlZnSnO, GaZnSnO, and ZrZnSnO, but is not limited thereto. The semiconductor material layer 310 may further include at least one dopant selected from among aluminum (Al), boron (B), arsenic (As), fluorine (F), and hydrogen (H) in addition to at least one oxide semiconductor material selected from the oxide semiconductor materials described above.

The insulating material layer 320 may include an insulating material. The insulating material layer 320 may include silicon oxide (SiO₂). However, without being limited thereto, the insulating material layer 320 may include other insulating materials such as silicon nitride (SiN), silicon oxynitride (SiON), etc.

The semiconductor material layer 310 and the insulating material layer 320 may include different materials from each other. The semiconductor material layer 310 and the insulating material layer 320 may include materials having different etch rates under the same conditions. The semiconductor material layer 310 and the insulating material layer 320 may have different etch rates, and the insulating material layer 320 may be selectively removed in a subsequent process.

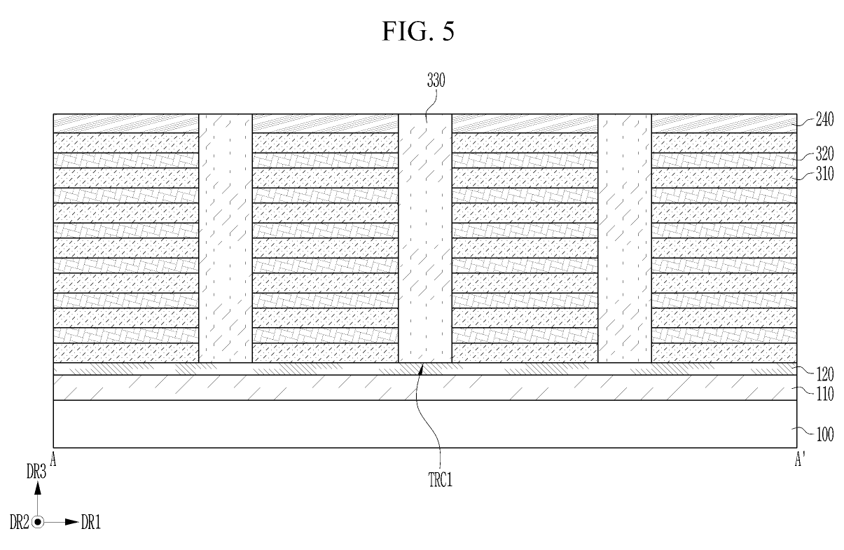

Next, referring to FIG. 5, the upper insulating layer 240 may be formed on the uppermost one of the semiconductor material layers 310, and a plurality of capping insulating layers 330 spaced apart in the first direction DR1 may be formed on the etch stop layer 120.

First, the upper insulating layer 240 may be formed on the uppermost one of the semiconductor material layers 310.

Next, the upper insulating layer 240, the semiconductor material layer 310 and the insulating material layer 320 may be patterned to form a plurality of first trenches TRC1 spaced apart in the first direction DR1 and having a depth in the third direction DR3. A portion of the upper surface of the etch stop layer 120 may be exposed by the plurality of first trenches TRC1. Thereafter, the capping insulating layer 330 including an insulating material may be formed within the plurality of first trenches TRC1. Here, according to some embodiments, an isolation pattern having a shape extending in the first direction DR1 may be positioned between the plurality of capping insulating layers 330 in the second direction DR2.

The plurality of capping insulating layers 330 may be positioned spaced apart from each other in the first direction DR1. Additionally, the plurality of capping insulating layers 330 may be positioned spaced apart from each other in the second direction DR2. The upper insulating layer 240, a semiconductor material layer 310, and an insulating material layer 320 may be positioned between the plurality of capping insulating layers 330 in the first direction DR1. The isolation pattern and the upper insulating layer 240 may be positioned between the plurality of capping insulating layers 330 in the second direction DR2. The upper surface of the capping insulating layer 330 may be positioned at a same level as a level of the upper surface of the upper insulating layer 240 in the third direction DR3, but is not limited thereto.

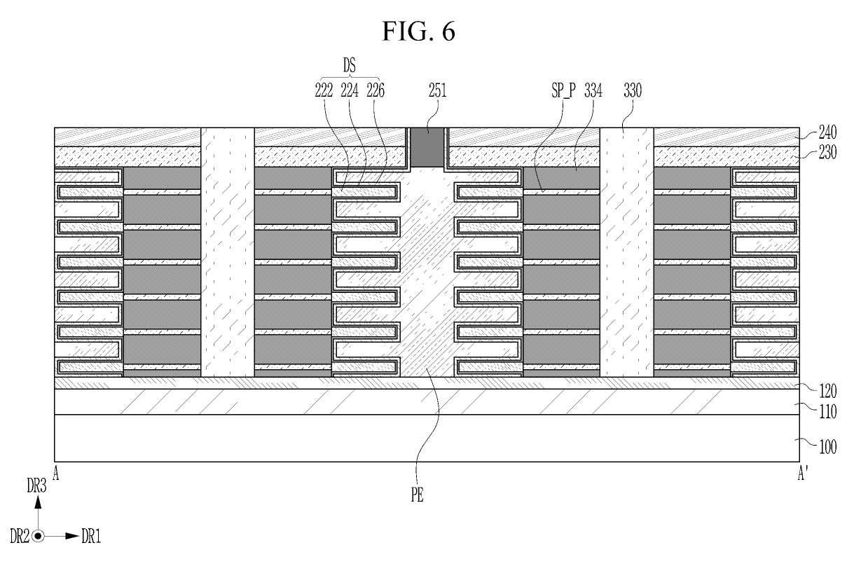

Next, referring to FIG. 6, some of the plurality of capping insulating layers 330 may be removed. And a preliminary semiconductor patterns SP_P, the data storage elements DS, the plate electrode PE, and the first connection pad 251 may be formed.

First, among the plurality of capping insulating layers 330 spaced apart and arranged in the first direction DR1, the capping insulating layers 330 positioned at every other location may be removed. For example, capping insulating layers 330 positioned at odd-numbered locations in the first direction DR1 may be removed. As another example, capping insulating layers 330 positioned at even-numbered locations in the first direction DR1 may be removed.

Next, the capping insulating layers 330 may be removed so that the semiconductor material layers 310 and the insulating material layers 320 are exposed to the outside, and the insulating material layers 320 may be selectively removed. In this process, the isolation pattern that isolates the semiconductor material layers 310 in the second direction DR2 may also be removed.

Next, a thinning process may be performed to remove a portion of the semiconductor material layer 310 to form a preliminary semiconductor pattern SP_P. Through the thinning process, the semiconductor material layer 310 may be replaced with a preliminary semiconductor pattern SP_P by reducing at least one from among the length in the first direction DR1, the width in the second direction DR2, and the thickness in the third direction DR3. In some embodiments, the thinning process of the semiconductor material layer 310 may be omitted. The plurality of preliminary semiconductor patterns SP_P may have a shape extending in the first direction DR1 from the capping insulating layer 330.

Next, a first preliminary insulating layer 334 may be formed to surround opposite side surfaces, in the first direction DR1, of the plurality of bit lines BL and the plurality of preliminary semiconductor patterns SP_P.

Next, the preliminary semiconductor pattern SP_P and a portion of the first preliminary insulating layer 334 may be removed. Specifically, an end of the preliminary semiconductor pattern SP_P covered by the first preliminary insulating layer 334 and a portion of the first preliminary insulating layer 334 covering the end of the preliminary semiconductor pattern SP_P may be removed. In this process, a portion of the first preliminary insulating layer 334 that overlapped with the removed portion of the preliminary semiconductor pattern SP_P in the third direction DR3 may remain. Additionally, in this process, the length of the preliminary semiconductor pattern SP_P in the first direction DR1 may be shortened.

Next, the plurality of first electrodes 222 may be formed so as to be respectively connected to the ends of the plurality of preliminary semiconductor patterns SP_P, and the dielectric film 224 and the second electrode 226 may be sequentially formed so as to conformally cover the plurality of first electrodes 222. The dielectric film 224 and the second electrode 226 may extend in the third direction DR3 to the upper surface of the upper insulating layer 240.

Next, the plate electrode PE may be formed to cover the plurality of second electrodes 226. The plate electrode PE may be formed to fill the space between the plurality of opposing preliminary semiconductor patterns SP_P. The plate electrode PE may be formed so that its lowermost surface is in contact with the etch stop layer 120. The first connection pad 251 may be formed on the plate electrode PE.

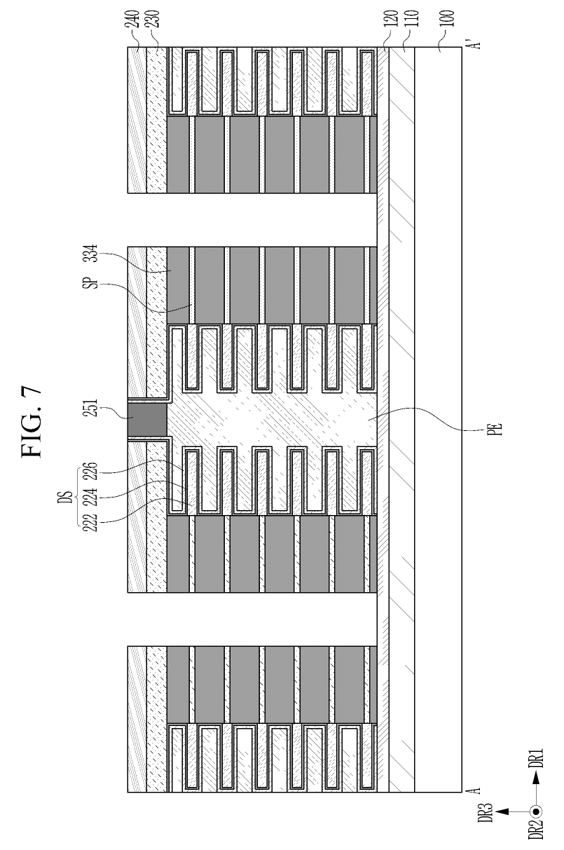

Next, referring to FIG. 7, the remaining portion of the capping insulating layer 330 may be removed, the preliminary semiconductor pattern SP_P may be removed, and then the semiconductor pattern SP may be formed at the location of the preliminary semiconductor pattern SP_P.

First, the remaining portion of the capping insulating layer 330 may be selectively removed. Thereafter, as the capping insulating layer 330 is removed, an end of the preliminary semiconductor pattern SP_P may be exposed. The end of the preliminary semiconductor pattern SP_P that is externally exposed may mean an end in the first direction DR1 opposite to the end of the preliminary semiconductor pattern SP_P connected to the data storage element DS.

Next, the plurality of preliminary semiconductor patterns SP_P may be selectively removed, and the plurality of semiconductor patterns SP may be respectively formed at the positions where the plurality of preliminary semiconductor patterns SP_P were previously positioned. The preliminary semiconductor pattern SP_P and the semiconductor pattern SP may include different semiconductor materials from each other. By way of example, the preliminary semiconductor pattern SP_P may include polysilicon, and the semiconductor pattern SP may include an oxide semiconductor material, but is not limited thereto. Here, the oxide semiconductor material may be formed of at least one selected from among IGZO (InGaZnO), ZrOx, ZTO (ZnSnO), ITZO (InSnZnO), Sn-IGZO, IWO (InWO), IZO (InZnO), ZnO, ZnON, YZO (yttrium-doped zinc oxide), InGaSiO, InO, SnO, TiO, ZnON, MgZnO, InZnO, ZrInZnO, HfInZnO, SnInZnO, AlSnInZnO, SiInZnO, AlZnSnO, GaZnSnO, and ZrZnSnO, but is not limited thereto. The semiconductor pattern SP may further include at least one dopant selected from among aluminum (Al), boron (B), arsenic (As), fluorine (F), and hydrogen (H), in addition to at least one oxide semiconductor material selected from the above-mentioned oxide semiconductor materials.

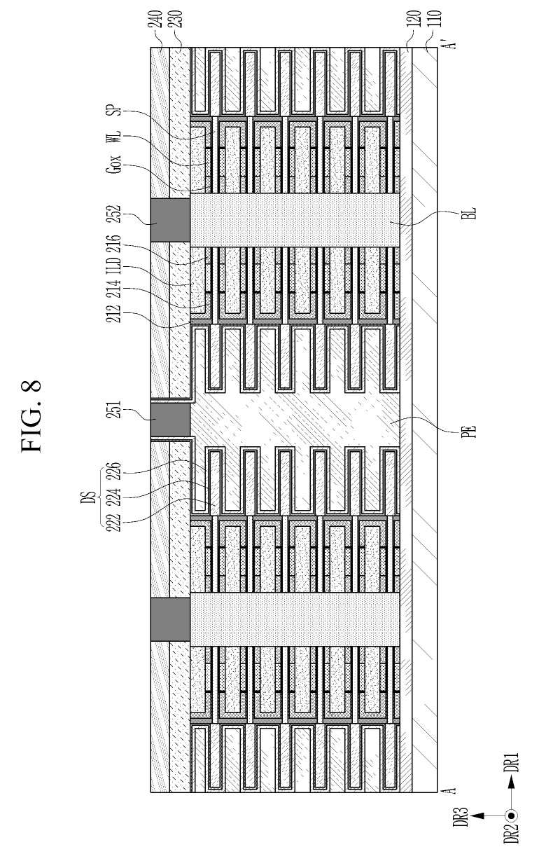

Next, referring to FIG. 8, the intermediate insulating layer 212, the first spacer 214, the gate insulating pattern Gox, the word line WL, the second spacer 216, the interlayer dielectric layer ILD, the bit line BL, and the second connection pad 252 positioned on the bit line BL may be formed.

First, the first preliminary insulating layer 334 may be recessed in the direction of the data storage element DS and plate electrode PE, and the intermediate insulating layer 212 may be formed. As the first preliminary insulating layer 334 is recessed, a portion of the upper and lower surfaces of the semiconductor pattern SP and a portion of the side surface in the second direction DR2 may be exposed.

Next, the first spacer 214 and the interlayer dielectric layer ILD may be formed in the space formed in a recessed region of the first preliminary insulating layer 334, and the gate insulating pattern Gox, the word line WL, and the second spacer 216 may be formed in sequence.

Next, the bit line BL may be formed to be connected to one end of the semiconductor pattern SP. Here, according to some embodiments, after forming the separation insulating pattern 218 of FIG. 3, the bit line BL may be formed. Accordingly, the plurality of bit lines BL may be formed to be spaced apart in the second direction DR2 with the separation insulating pattern 218 therebetween.

Next, the second connection pad 252 may be formed on the bit line BL. The side surfaces of the second connection pad 252 on the bit line BL may be covered by the shield layer 230 and the upper insulating layer 240. According to some embodiments, an additional insulating layer may be positioned between the second connecting pad 252 and the shield layer 230.

Next, the substrate 100 may be removed. For example, the substrate 100 may be removed through a grinding process. In the grinding process for removing the substrate 100, the polishing stop layer 110 may serve as a stop layer.

FIGS. 9 and 10 are cross-sectional views of semiconductor devices according to other embodiments.

Referring to FIG. 9, a semiconductor device according to another embodiment may include a cell structure CS, a peripheral circuit structure PS, and a at least one through via 532 connecting the cell structure CS and the peripheral circuit structure PS.

The cell structure CS may include the configuration of the semiconductor device described with reference to FIGS. 1 to FIG. 3. For example, the cell structure CS may include the polishing stop layer 110, the etch stop layer 120, the word lines WL, the gate insulating pattern Gox, the semiconductor pattern SP, the interlayer dielectric layers ILD, the bit lines BL of FIG. 1, the data storage elements DS of FIG. 1, a word line contact WLC, a cell insulating layer 219, the shield layer 230, the upper insulating layer 240, a cell wiring structure CW, and a cell buffer layer 430.

The etch stop layer 120 may be positioned on the polishing stop layer 110. The plurality of word lines WL may be positioned on the etch stop layer 120. The plurality of word lines WL may be positioned spaced apart in the third direction DR3 with the interlayer dielectric layer ILD therebetween. The plurality of word lines WL may be positioned to surround the plurality of semiconductor patterns SP spaced apart from each other in the second direction DR2. The gate insulating pattern Gox may be positioned between the word line WL and the semiconductor pattern SP. The shield layer 230 may be positioned on the plurality of interlayer dielectric layers ILD and the plurality of word lines WL. The upper insulating layer 240 may be positioned on the shield layer 230.

The etch stop layer 120 may be positioned on the first surface of the polishing stop layer 110. The second surface of the polishing stop layer 110 may be a surface facing the first surface in the third direction DR3. For example, the first surface of the polishing stop layer 110 may mean the upper surface of the polishing stop layer 110, and the second surface of the polishing stop layer 110 may mean the lower surface of the polishing stop layer 110. The first surface of the polishing stop layer 110 may be positioned to face the second surface of a peripheral substrate 510.

The word line WL may be positioned on the first surface of the etch stop layer 120. The semiconductor pattern SP may be positioned on the first surface of the etch stop layer 120. The interlayer dielectric layer ILD may be positioned on the first surface of the etch stop layer 120. The cell wiring structure CW may be positioned on the first surface of the etch stop layer 120. The polishing stop layer 110 may be positioned on the second surface of the etch stop layer 120. The first and second surfaces of the etch stop layer 120 may be surfaces facing each other in the third direction DR3. For example, the first surface of the etch stop layer 120 may mean the upper surface of the etch stop layer 120, and the second surface of the etch stop layer 120 may mean the lower surface of the etch stop layer 120. The first surface of the etch stop layer 120 may be positioned to face the second surface of the peripheral substrate 510.

The plurality of interlayer dielectric layers ILD and the plurality of word lines WL may be alternately stacked in the third direction DR3. The interlayer dielectric layer ILD and the word line WL may have a form extending in the second direction DR2. The lengths of a plurality of word lines WL and interlayer dielectric layers ILD positioned to be spaced apart in the third direction DR3 may be different from each other in the second direction DR2. For example, the word line WL and the interlayer dielectric layer ILD positioned at the lowest level, among the word lines WL and the interlayer dielectric layers ILD, in the third direction DR3 may have the greatest length in the second direction DR2, and the lengths of the among the word lines WL and the interlayer dielectric layers ILD in the second direction DR2 may gradually decrease toward the upper layers thereof.

For example, the length of each of the plurality of interlayer dielectric layers ILD in the second direction DR2 may be different. For example, the plurality of interlayer dielectric layers ILD may extend to different degrees in the second direction DR2. Among the plurality of interlayer dielectric layers ILD, the interlayer dielectric layer ILD positioned at the lowest layer may extend the longest in the second direction DR2, and the extent of extension in the second direction DR2 may become smaller as it goes upward in the third direction DR3, but is not limited thereto.

For example, the length of each of the plurality of word lines WL in the second direction DR2 may be different. For example, the plurality of word lines WL may extend to different degrees in the second direction DR2. Among the plurality of word lines WL, the word line WL positioned at the lowest layer may extend the longest in the second direction DR2, and the extent to which it extends in the second direction DR2 may become smaller as it goes upward in the third direction DR3, but is not limited thereto.

Each of the plurality of word lines WL may be connected to a corresponding word line contact WLC. For example, each of the plurality of word lines WL may be connected to the word line contact WLC in a region that does not overlap with other word lines WL thereabove in the third direction DR3. The word line contact WLC may have a form extending in the third direction DR3. The cell insulating layer 219 may be positioned to surround the side of the word line contact WLC.

The word line contact WLC may penetrate the cell insulating layer 219, the shield layer 230, and the upper insulating layer 240 and be connected to the cell wiring structure CW positioned on the upper insulating layer 240. An insulating layer may be additionally provided between the word line contact WLC and the shield layer 230.

The cell wiring structure CW may include at least one first wiring 412, at least one via 414, at least one second wiring 416, and a cell wiring insulating layer 420.

The cell wiring structure CW may include a plurality of first wirings 412. Some of the plurality of first wirings 412 may be connected to the word line contacts WLC.

The cell wiring structure CW may include a plurality of second wirings 416. The second wiring 416 may be positioned above the first wiring 412.

The cell wiring structure CW may include the plurality of vias 414. The via 414 may be positioned between the first wiring 412 and the second wiring 416. The via 414 may connect the first wiring 412 and the second wiring 416. The via 414 may have a shape extending in the third direction DR3.

The first wiring 412, the via 414, and the second wiring 416 may include a conductive material. By way of example, the first wiring 412, the via 414, and the second wiring 416 may include, but are not limited to, metals such as copper (Cu), tungsten (W), metal oxides, metal nitrides, or doped semiconductor materials.

The cell wiring insulating layer 420 may cover the first wiring 412, the via 414, and the second wiring 416. The cell wiring insulating layer 420 may include an insulating material. By way of example, the cell wiring insulating layer 420 may include, but is not limited to, silicon oxide (SiO₂), silicon nitride (SiN), or silicon oxynitride (SiON).

In FIG. 9, the lower surface of the cell wiring insulating layer 420 and the lower surface of the first wiring 412 are illustrated to be positioned at a same level in the third direction DR3, and the upper surface of the cell wiring insulating layer 420 and the upper surface of the second wiring 416 are illustrated to be positioned at a same level in the third direction DR3, but this is not limited thereto. The cell wiring structure CW may include additional wirings in addition to the first wiring 412, the via 414, and the second wiring 416.

The cell buffer layer 430 may be positioned on the cell wiring structure CW. The cell buffer layer 430 may be positioned between the peripheral circuit structure PS and the cell wiring structure CW. The cell buffer layer 430 may be configured to reduce stress generation at the interface between the peripheral circuit structure PS and the cell structure CS. The cell buffer layer 430 may be configured to provide bonding between the peripheral circuit structure PS and the cell structure CS. By way of example, the cell buffer layer 430 may include, but is not limited to, an adhesive material. The cell buffer layer 430 may include an insulating material. By way of example, the cell buffer layer 430 may include, but is not limited to, silicon oxide (SiO₂), silicon nitride (SiN), or silicon oxynitride (SiON).

The peripheral circuit structure PS may be positioned on the cell structure CS. The peripheral circuit structure PS may include the peripheral substrate 510, a substrate insulating pattern 512, a peripheral circuit PC, a peripheral circuit insulating layer 520, a peripheral circuit wiring layer 530, and a peripheral circuit buffer layer 540.

The peripheral substrate 510 may include a semiconductor material. For example, the peripheral substrate 510 may be a semiconductor substrate including a semiconductor material, such as a single crystal Si substrate, a silicon-germanium (Si-Ge) substrate, or a Si-On-Insulator (SOI) substrate. As another example, the peripheral substrate 510 may be a semiconductor epitaxial layer including a semiconductor material. However, the type of the peripheral substrate 510 is not limited to this and may be changed in various ways.

The peripheral circuit PC may be positioned on the first surface of the peripheral substrate 510. The peripheral circuit insulating layer 520 may be positioned on the first surface of the peripheral substrate 510. The peripheral circuit buffer layer 540 may be positioned on the second surface of the peripheral substrate 510. The cell wiring structure CW may be positioned on the second surface of the peripheral substrate 510. The first surface and the second surface of the peripheral substrate 510 may be surfaces facing away from each other in the third direction DR3. For example, the first surface of the peripheral substrate 510 may mean the upper surface of the peripheral substrate 510, and the second surface of the peripheral substrate 510 may mean the lower surface of the peripheral substrate 510. The second surface of the peripheral substrate 510 may be positioned to face towards the first surface of the etch stop layer 120.

The substrate insulating pattern 512 may be positioned within the peripheral substrate 510. The substrate insulating pattern 512 may be positioned in a form that penetrates the peripheral substrate 510 in the third direction DR3. The substrate insulating pattern 512 may be positioned between the peripheral substrate 510 and the through via 532. The substrate insulating pattern 512 may be positioned to cover a portion of the side surface of the through via 532. The substrate insulating pattern 512 may electrically isolate the through via 532 and the peripheral substrate 510.

The width of the substrate insulating pattern 512 in the first direction DR1 may decrease as it extends from an upper portion of the substrate insulating pattern 512 to a lower portion of the substrate insulating pattern 512 in the third direction DR3. Additionally, the substrate insulating pattern 512 may have a width in the second direction DR2 that decreases as it extends from an upper portion of the substrate insulating pattern 512 to a lower portion of the substrate insulating pattern 512 in the third direction DR3. In other words, the substrate insulating pattern 512 may have a width that increases in the first direction DR1 and/or the second direction DR2 from an lower portion of the substrate insulating pattern 512 to a upper portion of the substrate insulating pattern 512 in the third direction DR3.

The substrate insulating pattern 512 may include an insulating material. By way of example, the substrate insulating pattern 512 may include, but is not limited to, silicon oxide (SiO₂), silicon nitride (SiN), or silicon oxynitride (SiON).

The peripheral circuit PC may be positioned on the peripheral substrate 510. A plurality of the peripheral circuits PC may be positioned on the peripheral substrate 510. The peripheral circuit PC may be connected to the peripheral circuit wiring layer 530.

The peripheral circuit PC may be configured to drive the components positioned in the cell structure CS. The peripheral circuits PC may be circuits that perform logical operations and may be composed of a combination of circuit elements such as transistors. For example, the peripheral circuit PC may include, but is not limited to, a row decoder that selects a row of a memory cell array based on an address signal, a column decoder that selects a column of the memory cell array based on the address signal, a sense amplifier that senses and amplifies data of a memory cell, and a word line driver that activates a word line of a selected row. For example, the peripheral circuit PC may include a gate all around (GAA) structure, a multi bridge channel field effect transistor (MBCFET^{TM}) structure, etc., in which four sides of the channel are surrounded by gate electrodes. However, embodiments are not limited thereto, and the peripheral circuit PC may have a fin field effect transistor (FinFET) structure, or may include a 3D stack field effect transistor (3DSFET) structure or a complementary field effect transistor (CFET) structure.

The peripheral circuit insulating layer 520 may be positioned on the peripheral substrate 510. The peripheral circuit insulating layer 520 may cover a portion of the upper surface of the peripheral substrate 510 and the plurality of peripheral circuits PC. The peripheral circuit insulating layer 520 may include an insulating material. By way of example, the peripheral circuit insulating layer 520 may include, but is not limited to, silicon oxide (SiO₂), silicon nitride (SiN), or silicon oxynitride (SiON).

The peripheral circuit wiring layer 530 may be positioned above the peripheral circuit PC. The peripheral circuit wiring layer 530 may be positioned on the peripheral circuit insulating layer 520. According to some embodiments, the peripheral circuit wiring layer 530 may include a plurality of wirings and a plurality of vias connecting the wirings. Additionally, the peripheral circuit wiring layer 530 may include an insulating layer covering a plurality of wirings and a plurality of vias.

The peripheral circuit buffer layer 540 may be positioned below the peripheral substrate 510. The peripheral circuit buffer layer 540 may be positioned on the lower surface of the peripheral substrate 510. The peripheral circuit buffer layer 540 may be positioned on the cell buffer layer 430. The peripheral circuit buffer layer 540 may be in contact with the peripheral substrate 510. The peripheral circuit buffer layer 540 may be in contact with the lower surface of the peripheral substrate 510.

The peripheral circuit buffer layer 540 may include an insulating material. By way of example, the peripheral circuit buffer layer 540 may include, but is not limited to, silicon oxide (SiO₂), silicon nitride (SiN), or silicon oxynitride (SiON).

The through via 532 may connect the peripheral circuit wiring layer 530 and the cell wiring structure CW. For example, the through via 532 may connect the second wiring 416 of the cell wiring structure CW to a wiring positioned within the peripheral circuit wiring layer 530.

The through via 532 may have a shape extending in the third direction DR3. A plurality of the through vias 532 may be provided within the semiconductor device. The through via 532 may be positioned to penetrate the peripheral circuit wiring layer 530, the peripheral circuit insulating layer 520, the peripheral substrate 510, the peripheral circuit buffer layer 540, and the cell buffer layer 430 in the third direction DR3. The through via 532 may be positioned to penetrate the substrate insulating pattern 512 positioned within the peripheral substrate 510. A portion of the side of the through via 532 may be surrounded by the substrate insulating pattern 512.

The through via 532 may have a width in the first direction DR1 that decreases from an upper portion of the through via 532 to a lower portion of the through via 532 in the third direction DR3. Additionally, The through via 532 may have a width in the second direction DR2 that decreases from an upper portion of the through via 532 to a lower portion of the through via 532 in the third direction DR3.

The through via 532 may include a conductive material. By way of example, the through via 532 may include any one from among a doped semiconductor material such as doped silicon (Si) or doped germanium (Ge); a conductive metal nitride such as titanium nitride (TiN) or tantalum nitride (TaN); a metal such as tungsten (W), titanium (Ti), or tantalum (Ta); or a metal-semiconductor compound such as tungsten silicide (WSiₓ), cobalt silicide (CoSiₓ), or titanium silicide (TiSiₓ).

Referring to FIG. 10, a semiconductor device according to another embodiment may include a first cell structure CS1, a second cell structure CS2, and a peripheral circuit structure PS.

The description of the semiconductor device shown in FIG. 10 will focus on the parts that are substantially different from the description of the semiconductor device shown in FIG. 9.

The semiconductor device according to another embodiment may include the first cell structure CS1, the second cell structure CS2, the peripheral circuit structure PS, and the through via 532 connecting the second cell structure CS2 and the peripheral circuit structure PS.

Although FIG. 10 illustrates two cell structures being stacked, embodiments are not limited thereto. For example, the semiconductor device according to another embodiment may have a structure in which three or more cell structures are stacked.

The first cell structure CS1 and the second cell structure CS2 may include part or all of the configuration of the semiconductor device described in FIGS. 1 to FIG. 3. For example, each of the first cell structure CS1 and the second cell structure CS2 may include the etch stop layer 120, the word lines WL, the gate insulating pattern Gox, the semiconductor patterns SP, the interlayer dielectric layers ILD, the bit line sBL of FIG. 1, the data storage elements DS of FIG. 1, etc.

The first cell structure CS1 may include the polishing stop layer 110. The first cell structure CS1 may not include the cell wiring structure CW and the cell buffer layer 430. Although FIG. 10 illustrates that the first cell structure CS1 does not include the shield layer and the upper insulating layer, embodiments are not limited thereto. For example, in some embodiments, the first cell structure CS1 may include the shield layer and the upper insulating layer.

For example, in a semiconductor device having three or more stacked cell structures, the lowest positioned cell structure may include the polishing stop layer.

According to some embodiments, the plurality of word lines WL of the first cell structure CS1 may be respectively connected to corresponding word line contacts. Each of the plurality of word lines WL of the first cell structure CS1 may be connected to the cell wiring structure CW included in the second cell structure CS2 through a respective word line contact. For example, the word line contacts connected to word lines WL of the first cell structure CS1 may penetrate the cell insulating layer of the first cell structure CS1, the etch stop layer 120 of the second cell structure CS2, the cell insulating layer 219 of the second cell structure CS2, the shield layer 230 of the second cell structure CS2, and the upper insulating layer 240 of the second cell structure CS2 in the third direction DR3 to be connected to the cell wiring structure CW of the second cell structure CS2.

The second cell structure CS2 may be positioned on the first cell structure CS1. The second cell structure CS2 may include the shield layer 230, the upper insulating layer 240, the cell wiring structure CW, the cell buffer layer 430, the word line contact WLC, and the cell insulating layer 219. The second cell structure CS2 may not include the polishing stop layer 110.

For example, in a semiconductor device having three or more stacked cell structures, the uppermost cell structure may include a cell wiring structure and a cell buffer layer.

The etch stop layer 120 of the second cell structure CS2 may include a plurality of third connection pads 253. The third connection pad 253 included in the etch stop layer 120 of the second cell structure CS2 may also be referred to as a contact electrode or a similar term. The plurality of third connection pads 253 of the etch stop layer 120 of the second cell structure CS2 may respectively connect the bit lines BL of the first cell structure CS1 to corresponding bit lines BL of the second cell structure CS2.

The third connection pads 253 included in the etch stop layer 120 of the second cell structure CS2 may be surrounded on their sides by the etch stop layer 120 of the second cell structure CS2. The upper surface of the third connection pad 253 included in the etch stop layer 120 of the second cell structure CS2 may be connected to the bit line BL of the second cell structure CS2. The lower surface of the third connection pad 253 included in the etch stop layer 120 of the second cell structure CS2 may be connected to the bit line BL of the first cell structure CS1. The third connection pads 253 included in the etch stop layer 120 of the second cell structure CS2 may include a conductive material.

The cell buffer layer 430 of the second cell structure CS2 may be in contact with the peripheral circuit buffer layer 540 of the peripheral circuit structure PS. The peripheral circuit structure PS may be positioned on the second cell structure CS2. The peripheral circuit wiring layer 530 of the peripheral circuit structure PS may be connected to the cell wiring structure CW of the second cell structure CS2 through the through via 532. The through via 532 may be positioned to penetrate the peripheral circuit wiring layer 530, the peripheral circuit insulating layer 520, the peripheral substrate 510, the peripheral circuit buffer layer 540, and the cell buffer layer 430 of the second cell structure CS2.

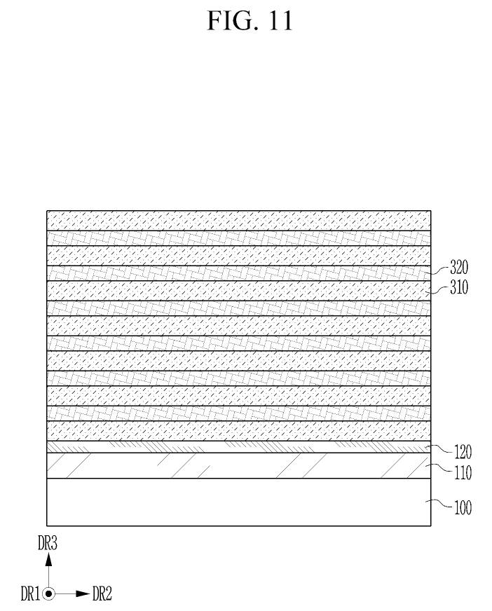

FIGS. 11 to FIG. 21 are views for illustrating methods of manufacturing semiconductor devices according to the other embodiments. In FIGS. 11 to FIG. 21, only a portion of the configuration is illustrated for convenience of explanation, and the first cell structure CS1 and the second cell structure CS2 may include some or all of the configurations of the semiconductor device described with reference to FIGS. 1 to FIG. 3.

Referring to FIG. 11, the polishing stop layer 110 may be formed on the substrate 100, and the etch stop layer 120 may be formed on the polishing stop layer 110.

Next, the plurality of semiconductor material layers 310 and the plurality of insulating material layers 320 may be alternately stacked on the etch stop layer 120. The semiconductor material layer 310 and the insulating material layer 320 may be formed by a deposition method.

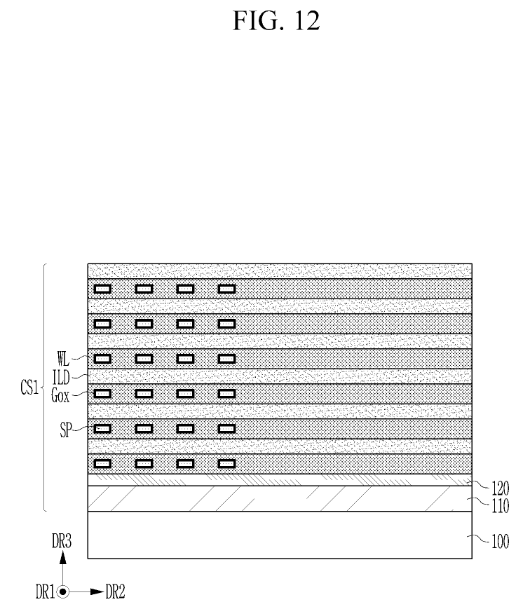

Next, referring to FIG. 12, the word lines WL, the interlayer dielectric layers ILD, the semiconductor patterns SP, and the gate insulating pattern Gox may be formed on the etch stop layer 120. That is, the first cell structure CS1 may be formed on the substrate 100.

According to some embodiments, the components included in the semiconductor devices of FIGS. 1 to FIG. 3 may be formed on the etch stop layer 120. For example, the bit lines BL of FIG. 1, the separation insulating pattern 218 of FIG. 1, the data storage elements DS of FIG. 1, the plate electrode PE of FIG. 1, the cell insulating layer, and other insulating patterns may be additionally formed on the etch stop layer 120.

Additionally, for example, a shield layer and an upper insulating layer may not be formed on the first cell structure CS1. The semiconductor material layer 310 positioned at the uppermost layer among the plurality of semiconductor material layers 310 may be removed during the process of forming the first cell structure CS1. Alternatively, one of the insulating material layers 320 may be formed to be positioned as the uppermost layer of the stacked structure during the process of stacking the plurality of semiconductor material layers 310 and the plurality of insulating material layers 320.

However, embodiments are not limited thereto, and in some embodiments, the shield layer and the upper insulating layer may be formed on the first cell structure CS1. The shield layer and the upper insulating layer may be formed to be positioned at the uppermost layer of the stacked structure including the plurality of semiconductor material layers 310 and the plurality of insulating material layers 320.

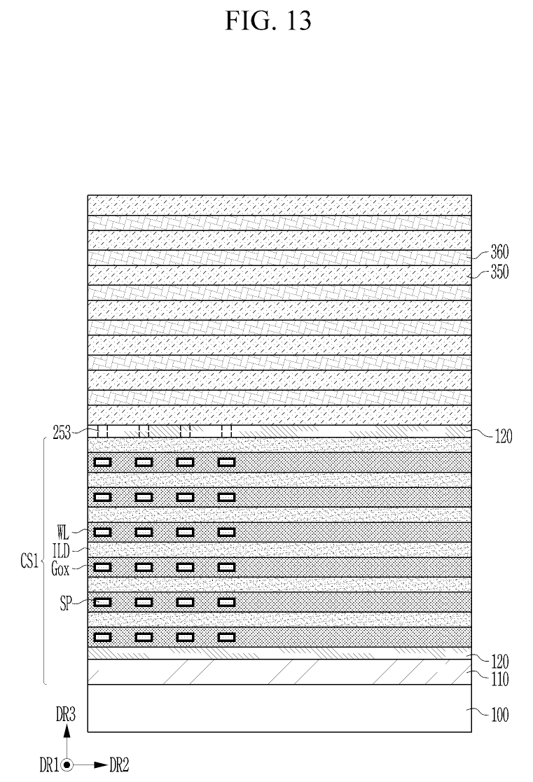

Next, referring to FIG. 13, the etch stop layer 120 may be formed on the first cell structure CS1 to form the second cell structure CS2. Additionally, the plurality of third connection pads 253 may be formed within the etch stop layer 120 on the first cell structure CS1. The plurality of third connection pads 253 may be formed to respectively connect to the bit lines of the first cell structure CS1. The bit lines of the first cell structure CS1 and the bit lines to be formed later may be connected respectively to each other by the plurality of third connection pads 253. Here, the third connection pads 253 may include a conductive material.

Next, the plurality of semiconductor material layers 350 and the plurality of insulating material layers 360 may be stacked alternately on the etch stop layer 120. The semiconductor material layer 350 and the insulating material layer 360 may be formed by a deposition method.

Here, the semiconductor material layer 350 and the insulating material layer 360 may be substantially identical to the semiconductor material layer 310 and the insulating material layer 320 of FIG. 11 for forming the first cell structure CS1.

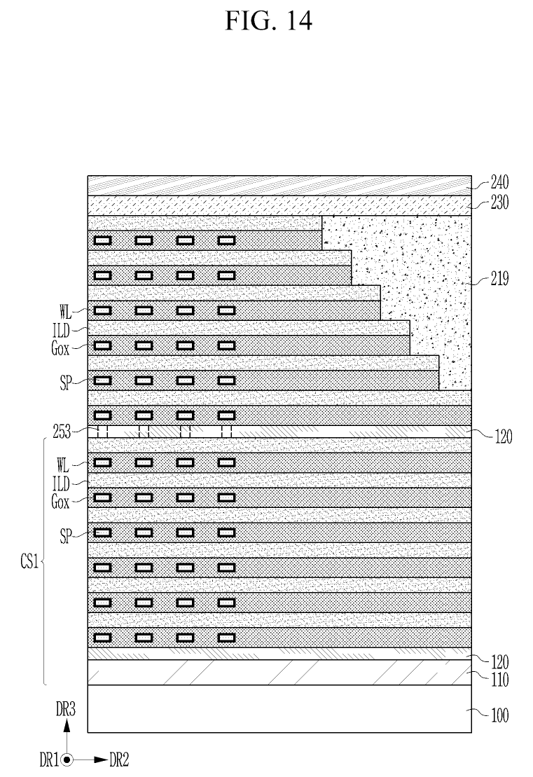

Next, referring to FIG. 14, the word lines WL, the interlayer dielectric layers ILD, the semiconductor patterns SP, the gate insulating pattern Gox, the shield layer 230, and the upper insulating layer 240 may be formed on the etch stop layer 120 positioned on the first cell structure CS1.

According to some embodiments, the configurations included in the semiconductor devices of FIGS. 1 to FIG. 3 may be formed. For example, the bit lines BL of FIG. 1, the separation insulating pattern 218 of FIG. 1, the data storage elements DS of FIG. 1, the plate electrode PE of FIG. 1, and other insulating layers and insulating patterns may be additionally formed on the etch stop layer 120 positioned on the first cell structure CS1.

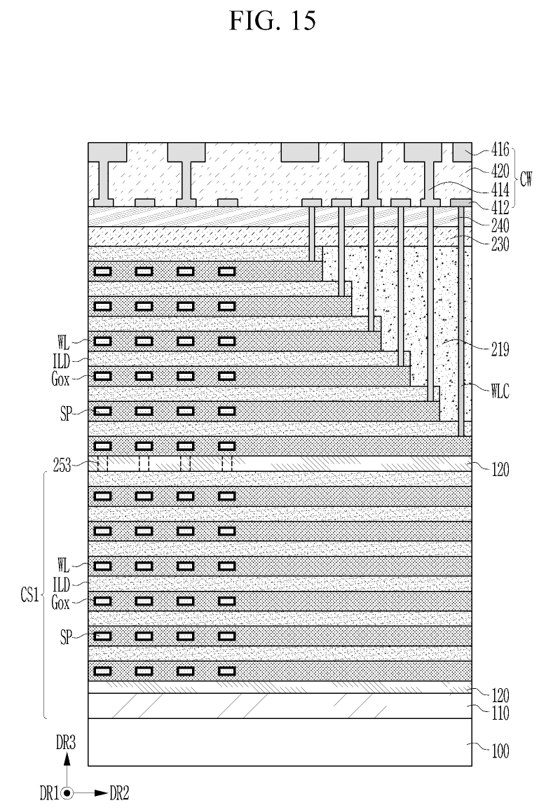

Next, referring to FIG. 15, the plurality of word line contacts WLC may be formed. Additionally, the cell wiring structure CW may be formed on the upper insulating layer 240.

The plurality of word line contacts WLC may be formed to be respectively connected to the plurality of word lines WL positioned on the substrate 100. For example, each of the plurality of word line contacts WLC may be formed to extend in the third direction DR3 from a corresponding one of the plurality of word lines WL to the upper surface of the upper insulating layer 240. The plurality of word lines WL of the cell wiring structure CW to be formed later and the plurality of word lines WL of the first cell structure CS1 may be connected by the plurality of word line contacts WLC. And the plurality of word lines WL of the cell wiring structure CW and the second cell structure CS2 may be connected by the plurality of word line contacts WLC.

Next, the cell wiring structure CW may be formed on the upper insulating layer 240. The cell wiring structures CW may include the first wirings 412, the vias 414, the second wirings 416, and the cell wiring insulating layer 420. For example, the first wiring 412 of the cell wiring structure CW may be connected to at least one of the plurality of word line contacts WLC connected to the first cell structure CS1 and the second cell structure CS. The first wiring 412 and the second wiring 416 may be connected by the plurality of vias 414.

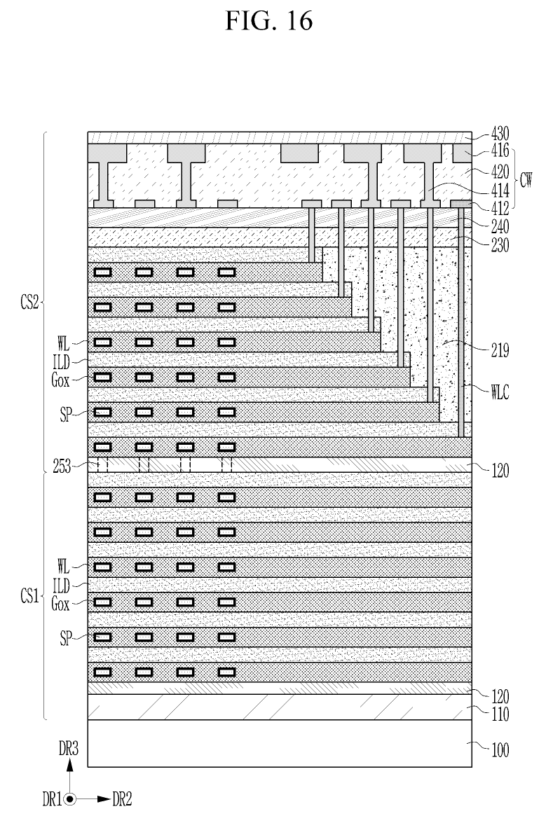

Next, referring to FIG. 16, the cell buffer layer 430 may be formed on the cell wiring structure CW. The cell buffer layer 430 may be configured to be in contact with the peripheral circuit structure PS that is formed later. For example, the cell buffer layer 430 may reduce stress that may occur at the interface between components, or may serve as a layer for bonding.

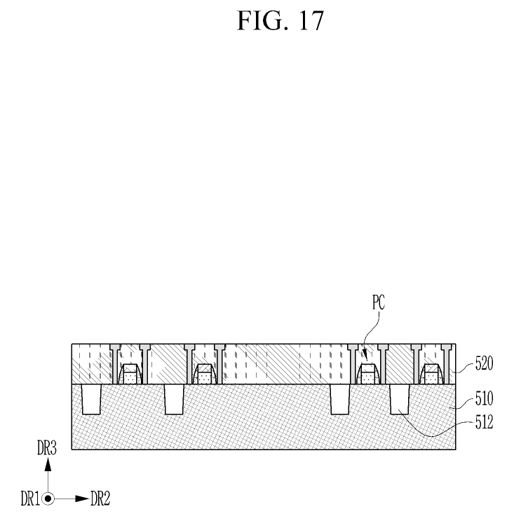

Meanwhile, referring to FIG. 17, the substrate insulating pattern 512, the plurality of peripheral circuits PC, and the peripheral circuit insulating layer 520 may be formed on the peripheral substrate 510.

First, the substrate insulating pattern 512 may be formed on the peripheral substrate 510. The substrate insulating pattern 512 may be formed to extend downward in the third direction DR3 from the first surface of the peripheral substrate 510. In other words, the substrate insulating pattern 512 may be formed within the peripheral substrate 510. For example, the substrate insulating pattern 512 may be formed such that its width in the first direction DR1 and the second direction DR2 decreases from top to bottom in the third direction DR3. That is, the substrate insulating pattern 512 may be formed such that its width in the first direction DR1 and the second direction DR2 increases from the bottom to the top in the third direction DR3.

Next, the plurality of peripheral circuits PC and the peripheral circuit insulating layer 520 may be formed. The plurality of peripheral circuits PC may be formed on the peripheral substrate 510. The plurality of peripheral circuits PC may be formed on the first surface of the peripheral substrate 510. The plurality of peripheral circuits PC may be formed not to overlap with the plurality of substrate insulating patterns 512 in the third direction DR3.

Next, the peripheral circuit insulating layer 520 may be formed to cover the plurality of peripheral circuits PC. The peripheral circuit insulating layer 520 may be formed on the first surface of the peripheral substrate 510. The peripheral circuit insulating layer 520 may be formed to cover the first surface of the peripheral substrate 510. The second surface of the peripheral circuit insulating layer 520 may be in contact with the peripheral substrate 510, and the first surface of the peripheral circuit insulating layer 520 may be a surface facing the second surface in the third direction DR3.

For example, the first surface of the peripheral substrate 510 and the peripheral circuit insulating layer 520 may mean the upper surface in the third direction DR3. Additionally, the second surface of the peripheral substrate 510 and the peripheral circuit insulating layer 520 may mean a lower surface in the third direction DR3.

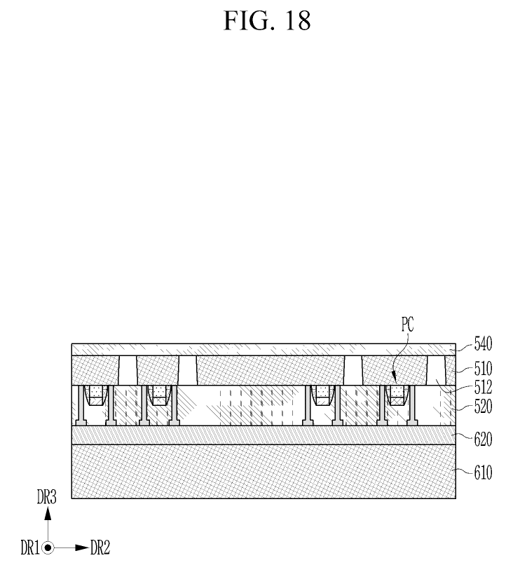

Next, referring to FIG. 18, an adhesive layer 620 may be formed on a carrier substrate 610. The adhesive layer 620 may include an insulating material and may additionally include an adhesive material, but is not limited thereto.

Next, the peripheral substrate 510 and the plurality of peripheral circuits PC may be placed on the carrier substrate 610. The plurality of peripheral circuits PC may be arranged on the carrier substrate 610 so that the peripheral circuit insulating layer 520 is in contact with the adhesive layer 620. Here, the second surface of the peripheral circuit insulating layer 520 may contact the adhesive layer 620. That is, the peripheral substrate 510 and the plurality of peripheral circuits PC may be arranged in an inverted state in the third direction DR3.

Specifically, the peripheral substrate 510 may be arranged in an inverted state so that the first side faces downward and the second side faces upward. Accordingly, the peripheral circuit insulating layer 520 may be positioned on the adhesive layer 620, and the peripheral substrate 510 may be positioned on the peripheral circuit insulating layer 520.

The thickness of the peripheral substrate 510 in the third direction DR3 may be reduced through a polishing process. Here, the process of polishing the peripheral substrate 510 may be performed before the peripheral substrate 510 is arranged on the carrier substrate 610, or may be performed after the peripheral substrate is arranged on the carrier substrate 610.

The peripheral circuit buffer layer 540 may be formed on the second surface of the peripheral substrate 510. The peripheral circuit buffer layer 540 may reduce stress that may occur at the interface between components, or may be used for bonding.

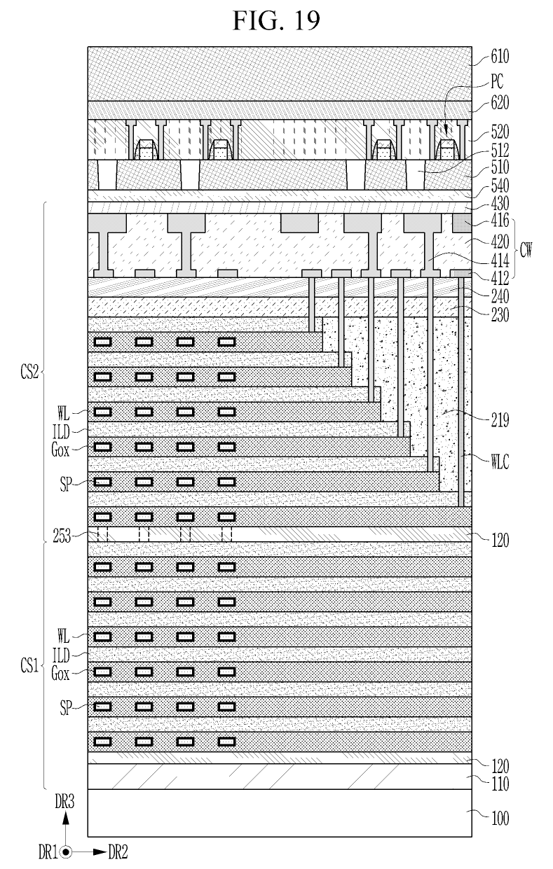

Next, referring to FIG. 19, the carrier substrate 610 may be arranged so that the peripheral circuit buffer layer 540 is in contact with the cell buffer layer 430. Accordingly, the peripheral circuit buffer layer 540 may be positioned on the cell buffer layer 430. Additionally, the peripheral substrate 510 may be positioned on the peripheral circuit buffer layer 540. Additionally, the adhesive layer 620 and the carrier substrate 610 may be positioned on the peripheral substrate 510.

In other words, the first surface of the peripheral substrate 510 may be arranged to face upward in the third direction DR3, and the second surface of the peripheral substrate 510 may be arranged to face downward in the third direction DR3.

The peripheral circuit PC, the peripheral circuit buffer layer 540, the adhesive layer 620, and the carrier substrate 610 may be positioned on the first surface of the peripheral substrate 510. The cell buffer layer 430 and the cell wiring structure CW may be positioned on the second surface of the peripheral substrate 510.

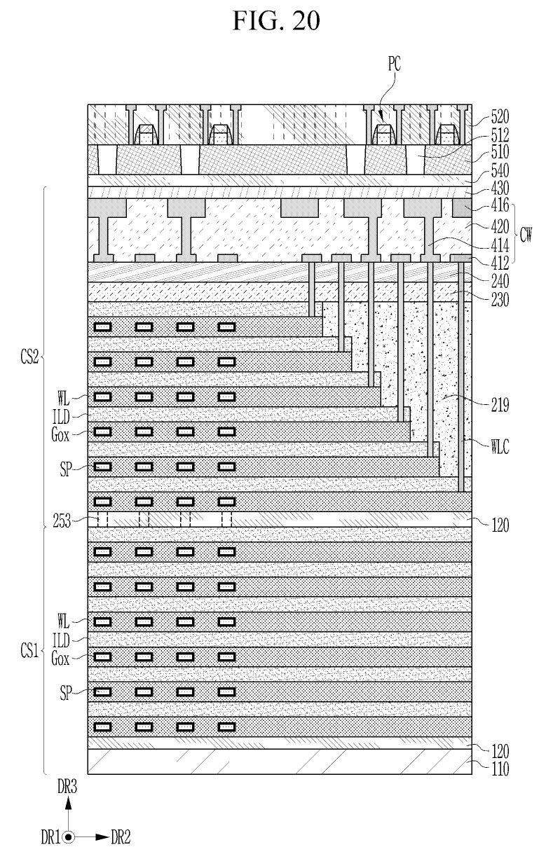

Next, referring to FIG. 20, the substrate 100, the carrier substrate 610, and the adhesive layer 620 may be removed. Specifically, the substrate 100 positioned on the second surface of the etch stop layer 120 and the polishing stop layer 110 may be removed. Additionally, the carrier substrate 610 and the adhesive layer 620 positioned on the first surface of the peripheral substrate 510 may be removed. For example, the substrate 100, the carrier substrate 610, and the adhesive layer 620 may be removed through a grinding process.

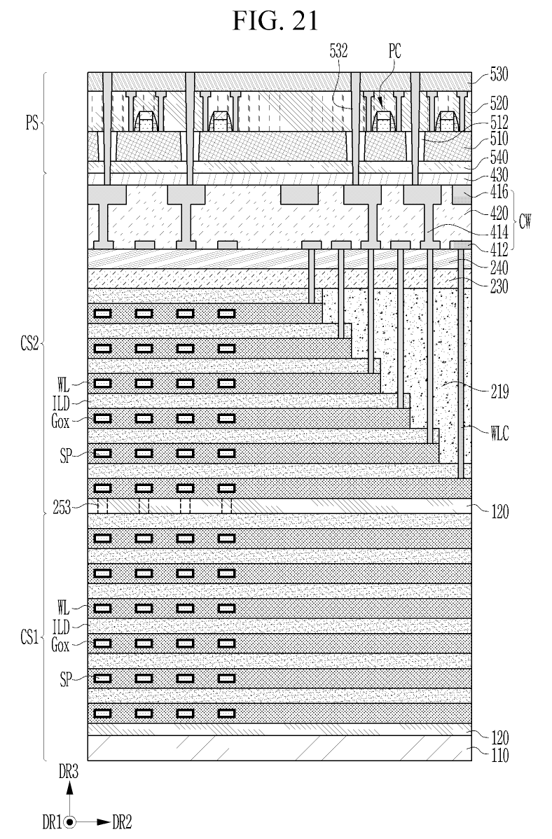

Next, referring to FIG. 21, the peripheral circuit wiring layer 530 and the plurality of the through vias 532 connecting the peripheral circuit wiring layer 530 and the cell wiring structure CW may be formed on the peripheral circuit PC and the peripheral circuit insulating layer 520.

The plurality of through vias 532 may be formed to penetrate the peripheral circuit insulating layer 520, the peripheral substrate 510, the peripheral circuit buffer layer 540, and the cell buffer layer 430 in the third direction DR3. The plurality of through vias 532 may be formed such that their widths in the first direction DR1 and the second direction DR2 decrease from an upper portion of the through vias 532 to a lower portion of the through vias 532 in the third direction DR3. That is, the plurality of through vias 532 may be formed so that the width in the first direction DR1 and the second direction DR2 increases from the bottom to the top in the third direction DR3.

The peripheral circuit wiring layer 530 may be formed to be connected to the plurality of peripheral circuits PC positioned on the peripheral substrate 510. According to some embodiments, the peripheral circuit wiring layer 530 may include the plurality of wiring lines and the plurality of vias. Additionally, the peripheral circuit wiring layer 530 may be connected to the cell wiring structure CW through the plurality of through vias 532.

According to the embodiments mentioned above, since the etch stop layers 120 have a flat shape, there may be no non-functioning semiconductor pattern SP. In addition, since the substrate 100 may be removed through a polishing process using the polishing stop layer 110 as a stop layer, there is an advantage in that the height of the overall semiconductor device may be controlled to be low. In addition, there is an advantage in that the wiring of the cell structure CS may be configured relatively easily by arranging the peripheral circuits PC of the peripheral circuit structure PS so that the peripheral circuits PC are positioned on the peripheral substrate 510 without being arranged upside down.

According to some embodiments of the present disclosure, a method of manufacturing a semiconductor device may include: forming a polishing stop layer on a substrate; forming an etch stop layer on the polishing stop layer; alternately stacking a plurality of semiconductor material layers and a plurality of insulating material layers on the etch stop layer; removing the plurality of insulating material layers, forming a plurality of preliminary semiconductor patterns from the semiconductor material layers, and forming a plurality of data storage elements, respectively connected to the preliminary semiconductor patterns, and a plate electrode ON the plurality of data storage elements; removing the plurality of preliminary semiconductor patterns and forming semiconductor patterns; forming a plurality of word lines respectively ON portions of upper and lower surfaces of corresponding ones of the semiconductor patterns, and forming a plurality of bit lines respectively connected to ends of the semiconductor patterns; and removing the substrate.

In the method of manufacturing the semiconductor device according to an embodiment, the plurality of semiconductor material layers and the plurality of insulating material layers may be formed by a deposition process.

In the method of manufacturing the semiconductor device according to an embodiment, the plurality of semiconductor material layers may include polysilicon, and the plurality of insulating material layers may include an insulating material.

In the method of manufacturing the semiconductor device according to an embodiment, the semiconductor patterns may include an oxide semiconductor material.

In the method of manufacturing the semiconductor device according to an embodiment, lower surfaces of the plurality of bit lines and a lower surface of the plate electrode may be positioned at A same level as a level of an upper surface of the etch stop layer.

According to some embodiments of the present disclosure, a method of manufacturing a semiconductor device may include: forming a first cell structure including a polishing stop layer on a substrate, an etch stop layer on the polishing stop layer, a plurality of semiconductor patterns on the etch stop layer, a plurality of word lines respectively on portions of upper and lower surfaces of corresponding ones of the semiconductor patterns, a plurality of interlayer dielectric layers between the word lines, gate insulating patterns between the word lines and the semiconductor patterns, and a cell wiring structure on the word lines; forming a peripheral circuit structure on the first cell structure, the peripheral circuit structure including a peripheral substrate, a plurality of peripheral circuits on a first surface of the peripheral substrate, a peripheral circuit insulating layer on the peripheral circuits, and a peripheral circuit wiring layer on the peripheral circuit insulating layer; removing the substrate; and forming a plurality of through vias connecting the cell wiring structure and the peripheral circuit wiring layer.

In the method of manufacturing the semiconductor device according to an embodiment, the plurality of word lines may be positioned on a first surface of the etch stop layer, the plurality of peripheral circuits may be positioned on a first surface of the peripheral substrate, the cell wiring structure may be positioned on a second surface of the peripheral substrate, and the first surface of the etch stop layer may be positioned to face the second surface of the peripheral substrate.

In the method of manufacturing the semiconductor device according to an embodiment, the plurality of through vias may extend through the peripheral substrate, and the peripheral substrate may further include a substrate insulating pattern on sidewalls of the through vias.

In the method of manufacturing the semiconductor device according to an embodiment, the widths of the plurality of through-vias and the substrate insulating pattern may decrease toward a lower portion of the plurality of through-vias and the substrate insulating pattern, respectively..

In the method of manufacturing the semiconductor device according to an embodiment, the cell structure may further comprise a plurality of word line contacts connecting the cell wiring structure and the plurality of word lines, and a cell insulating layer on the plurality of word line contacts.

Although non-limiting example embodiments of the present disclosure have been described in detail above with reference to the accompanying drawings, the scope of the present disclosure is not limited thereto, and various modifications and improvements made by those skilled in the art within the spirit and scope of the present disclosure.

What is claimed is:

1. A semiconductor device comprising:
a polishing stop layer,
an etch stop layer on an upper surface of the polishing stop layer,
a semiconductor pattern on an upper surface of the etch stop layer, the semiconductor pattern extending in a first direction,
a word line on at least a portion of an upper or lower surface of the semiconductor pattern, the word line extending in a second direction intersecting the first direction,
a bit line extending in a third direction intersecting the first direction and the second direction, and connected to a first end of the semiconductor pattern, and
a data storage element connected to a second end of the semiconductor pattern, opposite of the first end,
wherein an insulating material of the polishing stop layer is different from an insulating material of the etch stop layer.

2. The semiconductor device of claim 1,
wherein the semiconductor pattern comprises an oxide semiconductor material.

3. The semiconductor device of claim 1, further comprising:
a plate electrode on the data storage element,
wherein a level of a lower surface of the plate electrode in the third direction is the same as a level of the upper surface of the etch stop layer in the third direction.

4. The semiconductor device of claim 1, further comprising:
an additional bit line on the upper surface of the etch stop layer, the additional bit line spaced apart from the bit line in the second direction;
a separation insulating pattern between the bit line and the additional bit line,
wherein a level of a lower surface of the separation insulating pattern in the third direction is the same as a level of the upper surface of the etch stop layer in the third direction.

5. The semiconductor device of claim 1,
wherein the upper surface of the etch stop layer extends parallel to the first direction and the second direction, and comprises a planar shape.

6. The semiconductor device of claim 1, wherein the data storage element comprises:
a first electrode connected to the second end of the semiconductor pattern;
a second electrode on the first electrode; and
a dielectric film between the first electrode and the second electrode.

7. A semiconductor device comprising:
a cell structure, and
a peripheral circuit structure on an upper surface of the cell structure,
wherein the cell structure comprises:
a polishing stop layer comprising an insulating material,
an etch stop layer on an upper surface of the polishing stop layer, the etch stop layer comprising an insulating material different from the insulating material of the polishing stop layer;
a semiconductor pattern on an upper surface of the etch stop layer and extending in a first direction,
a word line on at least a portion of an upper or lower surface of the semiconductor pattern, the word line extending in a second direction intersecting the first direction,
a bit line extending in a third direction intersecting the first direction and the second direction, and connected to a first end of the semiconductor pattern,
a data storage element connected to a second end of the semiconductor pattern, opposite of the first end, and
a cell wiring structure on the bit line and connected to the word line, and
wherein the peripheral circuit structure comprises:
a peripheral substrate,
a peripheral circuit wiring layer on the peripheral substrate and connected to the cell wiring structure, and
a peripheral circuit between the peripheral circuit wiring layer and the peripheral substrate and connected to the peripheral circuit wiring layer.

8. The semiconductor device of claim 7,
wherein the semiconductor pattern of the cell structure comprises an oxide semiconductor material.

9. The semiconductor device of claim 7, further comprising
a plate electrode on the data storage element,
wherein a level of a lower surface of the plate electrode in the third direction is the same as a level of the upper surface of the etch stop layer in the third direction.

10. The semiconductor device of claim 7, further comprising:
an additional bit line on the upper surface of the etch stop layer, the additional bit line spaced apart from the bit line in the second direction;
a separation insulating pattern between the bit line and the additional bit line,
wherein a level of a lower surface of the separation insulating pattern in the third direction is the same as a level of the upper surface of the etch stop layer in the third direction.

11. The semiconductor device of claim 7,
wherein the upper surface of the etch stop layer extends parallel to the first direction and the second direction, and comprises a planar shape.

12. The semiconductor device of claim 7, further comprising:
a through via extending through the peripheral substrate and connecting the peripheral circuit wiring layer and the cell wiring structure.

13. The semiconductor device of claim 7,
wherein the semiconductor pattern is on the upper surface of the etch stop layer, and the polishing stop layer is on a lower surface of the etch stop layer, and
wherein the peripheral circuit is on a first surface of the peripheral substrate, and a second surface of the peripheral substrate, opposite of the first surface, faces towards the upper surface of the etch stop layer.

14. A semiconductor device comprising:
a first cell structure,
a second cell structure on an upper surface of the first cell structure, and
a peripheral circuit structure on an upper surface of the second cell structure,
wherein each of the first cell structure and the second cell structure comprises:
an etch stop layer comprising an insulating material,
a semiconductor pattern on an upper surface of the etch stop layer and extending in a first direction,
a word line on at least a portion of an upper or lower surface of the semiconductor pattern, the word line extending in a second direction intersecting the first direction,
a bit line extending in a third direction intersecting the first direction and the second direction, and connected to a first end of the semiconductor pattern, and
a data storage element connected to a second end of the semiconductor pattern, opposite of the first end,
wherein the first cell structure further comprises a polishing stop layer below the etch stop layer of the first cell structure, the polishing stop layer comprising an insulating material that is different from the insulating material of the etch stop layer of the first cell structure,
wherein the second cell structure further comprises a cell wiring structure on the bit line of the second cell structure and connected to the word line of the first cell structure and the word line of the second cell structure, and
wherein the peripheral circuit structure comprises:
a peripheral substrate,
a peripheral circuit wiring layer on the peripheral substrate and connected to the cell wiring structure of the second cell structure, and
a peripheral circuit between the peripheral circuit wiring layer and the peripheral substrate, and connected to the peripheral circuit wiring layer.

15. The semiconductor device of claim 14,
wherein the semiconductor pattern of the first cell structure and the semiconductor pattern of the second cell structure comprise an oxide semiconductor material.

16. The semiconductor device of claim 14,
wherein the first cell structure comprises a first plate electrode on the data storage element of the first cell structure,
wherein the second cell structure comprises a second plate electrode on the data storage element of the second cell structure, wherein a level of a lower surface of the first plate electrode of the first cell structure in the third direction is the same as a level of the upper surface of the etch stop layer of the first cell structure in the third direction, and
wherein a level of a lower surface of the second plate electrode of the second cell structure in the third direction is the same as a level of the upper surface of the etch stop layer of the second cell structure in the third direction.

17. The semiconductor device of claim 14,
wherein the first cell structure further comprises:
a first additional bit line on the upper surface of the etch stop layer of the first cell structure; and
a first separation insulating pattern between the first additional bit line and the bit line of the first cell structure,
wherein the second cell structure further comprises:
a second additional bit line on the upper surface of the etch stop layer of the second cell structure; and
a second separation insulating pattern between the second additional bit line and the bit line of the second cell structure,
wherein a level of a lower surface of the first separation insulating pattern in the third direction is the same as a level of the upper surface of the etch stop layer of the first cell structure, and
wherein a level of a lower surface of the second separation insulating pattern in the third direction is the same as a level of the upper surface of the etch stop layer of the second cell structure.

18. The semiconductor device of claim 14,
wherein the etch stop layer of the first cell structure and the etch stop layer of the second cell structure extend in the first direction and the second direction, and comprise a planar shape.

19. The semiconductor device of claim 14,
wherein the etch stop layer of the second cell structure comprises a connection pad, and
wherein the connection pad connects the bit line of the first cell structure and the bit line of the second cell structure.

20. The semiconductor device of claim 14, further comprising:
a through via extending through the peripheral substrate and connecting the peripheral circuit wiring layer and the cell wiring structure of the second cell structure, and
a substrate insulating pattern in the peripheral substrate and at least partially surrounding the through via,
wherein a width of the through via in the second direction and a width of the substrate insulating pattern in the second direction decrease toward a lower side of the through via and the substrate insulating pattern in the third direction, respectively.
